(19) United States
(12) Patent Application Publication
(10) Pub. No.: US 2026/0279444 A1
(43) Pub. Date: Sep. 17, 2026

(54) SEMICONDUCTOR MEMORY DEVICE

(71) Applicant: Kioxia Corporation, Tokyo (JP)

(72) Inventors: Tomoko KAJIYAMA, Kamakura Kanagawa (JP); Hayato KONNO, Yokohama Kanagawa (JP); Toshihiro SUZUKI, Ota Tokyo (JP); Ryosuke ISOMURA, Matsudo Chiba (JP); Kyosuke SANO, Yokohama Kanagawa (JP)

(21) Appl. No.: 19/333,011

(22) Filed: Sep. 18, 2025

(30) Foreign Application Priority Data
Mar. 13, 2025 (JP) 2025-040517

(51) Int. Cl. G11C 16/08; G11C 16/26

(52) U.S. Cl. CPC G11C 16/08; G11C 16/26

(57) ABSTRACT

A semiconductor memory device includes a word line, a plurality of memory cells having gates connected to the word line, and a control circuit. In a write operation of setting the memory cells to a first state, the control circuit repeatedly executes a loop operation of sequentially executing a verification operation and a program operation, executes first and second sensing operations in the verification operation of a first loop operation, the first sensing operation being an operation of determining whether a threshold voltage of each of the memory cells is equal to or higher than a first voltage, the second sensing operation being an operation of determining whether a threshold voltage of each of the memory cells is equal to or higher than a second voltage, and does not execute the first sensing operation in the verification operation of a second loop operation that is after the first loop operation.

### CROSS-REFERENCE TO RELATED APPLICATION(S)

This application is based upon and claims the benefit of priority from Japanese Patent Application No. 2025-040517, filed Mar. 13, 2025, the entire contents of which are incorporated herein by reference.

### FIELD

Embodiments described herein relate generally to a semiconductor memory device.

### BACKGROUND

A NAND flash memory is known as one type of a semiconductor memory device.

### BRIEF DESCRIPTION OF THE DRAWINGS

FIG. 1 is a block diagram showing an example of a configuration of a memory system including a semiconductor memory device and a host device according to an embodiment.

FIG. 2 is a block diagram showing an example of a configuration of the semiconductor memory device according to the embodiment.

FIG. 3 is a circuit diagram showing an example of a configuration of a memory cell array of the semiconductor memory device according to the embodiment.

FIG. 4 is a cross-sectional view showing an example of a structure of the memory cell array of the semiconductor memory device according to the embodiment.

FIG. 5 is a cross-sectional view along a V-V line of FIG. 4, showing an example of a cross-sectional structure of a memory pillar in the memory cell array of the semiconductor memory device according to the embodiment.

FIG. 6 is a schematic diagram showing an example of a threshold voltage distribution of a memory cell transistor in the memory cell array of the semiconductor memory device according to the embodiment.

FIG. 7 is a block diagram showing an example of a configuration of a sense amplifier module of the semiconductor memory device according to the embodiment.

FIG. 8 is a circuit diagram showing an example of a circuit configuration of a sense amplifier circuit provided in the semiconductor memory device according to the embodiment.

FIG. 9 is a timing chart showing an overview of a write operation of the semiconductor memory device according to the embodiment.

FIG. 10 is a diagram showing selection of a program operation during a write operation using the semiconductor memory device according to the embodiment.

FIG. 11 is a diagram showing a first sensing operation and a second sensing operation in a verification operation using the semiconductor memory device according to the embodiment.

FIG. 12 is a timing chart of the verification operation during the write operation using the semiconductor memory device according to the embodiment.

FIG. 13 is a timing chart of the program operation during the write operation using the semiconductor memory device according to the embodiment.

FIG. 14 is a diagram showing a relationship between a loop count and the verification operation during the write operation using the semiconductor memory device according to the embodiment.

FIG. 15 is a diagram showing a relationship between the loop count and a bit line voltage during the write operation using the semiconductor memory device according to the embodiment.

FIG. 16 is a diagram showing a relationship between the loop count and the verification operation during the write operation using the semiconductor memory device according to the embodiment.

FIG. 17 is a diagram showing a relationship between the loop count and the bit line voltage during the write operation using the semiconductor memory device according to the embodiment.

FIG. 18 is a diagram showing a write operation in a semiconductor memory device in a comparative example.

FIG. 19 is a block diagram showing an example of a configuration of a semiconductor memory device according to a first modification.

FIG. 20 is a block diagram showing an example of a configuration of a sense amplifier module of the semiconductor memory device according to the first modification.

FIG. 21 is a diagram showing selection of an operation during the write operation using the semiconductor memory device according to the first modification.

FIG. 22 is a flowchart showing the selection of the operation during the write operation using the semiconductor memory device according to the first modification.

FIG. 23 is a block diagram showing an example of a configuration of a semiconductor memory device according to a second modification.

FIG. 24 is a flowchart showing selection of an operation during a write operation using semiconductor memory device according to the second modification.

FIG. 25 is a block diagram showing an example of a configuration of a semiconductor memory device according to a third modification.

### DETAILED DESCRIPTION

A processing speed is improved in a semiconductor memory device according to embodiments.

In general, according to one embodiment, a semiconductor memory device includes a first word line, a plurality of first memory cells having gates connected to the first word line, and a control circuit. In a first write operation of setting the plurality of first memory cells to a first state, the control circuit repeatedly executes a loop operation of sequentially executing a verification operation of confirming a threshold voltage and a program operation of raising a threshold voltage, executes a first sensing operation and a second sensing operation in the verification operation of a first loop operation, the first sensing operation being an operation of determining whether a threshold voltage of each of the plurality of first memory cells is equal to or higher than a first voltage, and the second sensing operation being an operation of determining whether the threshold voltage of each of the plurality of first memory cells is equal to or higher than a second voltage higher than the first voltage, and does not execute the first sensing operation in the verification operation of a second loop operation that is after the first loop operation.

Hereinafter, embodiments will be described with reference to the drawings. In the following description, components with the same functions and configurations are denoted by the common reference numerals.

### 1. EMBODIMENTS

A semiconductor memory device according to an embodiment will be described below. The semiconductor memory device is described below using a NAND flash memory as an example.

### 1.1 Configuration

A configuration of the semiconductor memory device according to the embodiment will be described.

### 1.1.1 Memory System

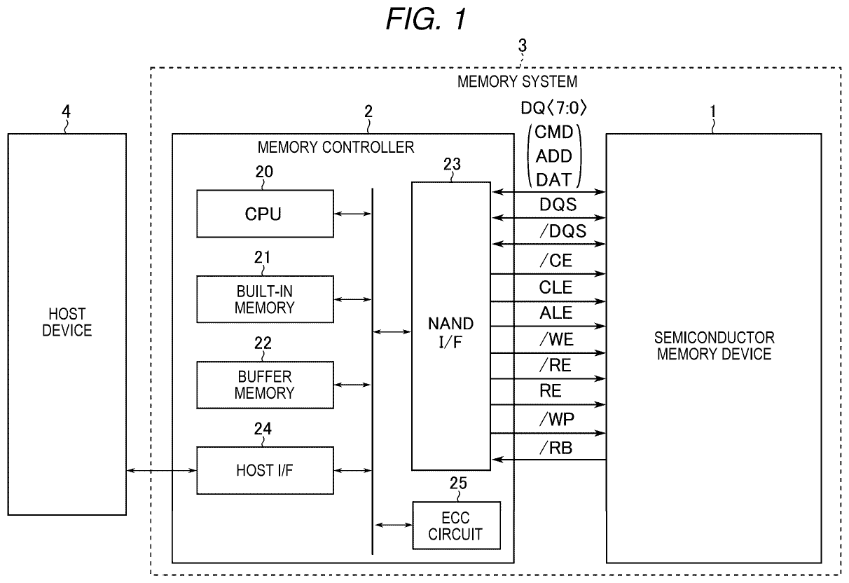

First, a configuration example of a memory system will be described with reference to FIG. 1. FIG. 1 is a block diagram showing an example of a configuration of the memory system including a semiconductor memory device and a host device according to the embodiment.

For example, a memory system 3 communicates with an external host device 4. The memory system 3 stores data from the host device 4. The memory system 3 reads data and sends it to the host device 4. The memory system 3 is, for example, a solid state drive (SSD) or an SD™ card.

The memory system 3 includes a semiconductor memory device 1 and a memory controller 2.

The semiconductor memory device 1 includes a plurality of memory cells and stores data in a non-volatile manner. The semiconductor memory device 1 is connected to the memory controller 2 via a NAND bus.

The NAND bus transmits and receives each of signals /CE, CLE, ALE, /WE, /RE, RE, /WP, /RB, DQ<7:0>, DQS, and/DQS according to a NAND interface via individual signal lines. The signal/CE is a chip enable signal for enabling the semiconductor memory device 1. The signal CLE is a command latch enable signal and notifies the semiconductor memory device 1 that the signal DQ<7:0> flowing into the semiconductor memory device 1 while the signal CLE is at an “H” level, is a command. The signal ALE is an address latch enable signal and notifies the semiconductor memory device 1 that the signal DQ<7:0> flowing into the semiconductor memory device 1 while the signal ALE is at an “H” level, is an address. The signal/WE is a write enable signal and instructs the semiconductor memory device 1 to latch the signal DQ<7:0>. For example, in single data rate (SDR), the signal/WE instructs the semiconductor memory device 1 to latch the signal DQ<7:0> as a command, an address, or data at a rising edge of the signal/WE. In double data rate (DDR), the signal/WE instructs the semiconductor memory device 1 to latch the signal DQ<7:0> as a command or an address on a rising edge of the signal/WE. The signal/RE is a read enable signal and instructs the semiconductor memory device 1 to output the signal DQ<7:0>. For example, in single data rate, the signal/RE instructs the semiconductor memory device 1 to output the signal DQ<7:0> as data on a falling edge of the signal/RE. In double data rate, the signal/RE instructs the semiconductor memory device 1 to output the signal DQ<7:0> as data on a falling edge and a rising edge of the signal/RE. The signal RE is a complementary signal of the signal/RE. The signal/WP is a write protect signal and instructs the semiconductor memory device 1 to prohibit data writing and erasing. The signal/RB is a ready busy signal and indicates whether the semiconductor memory device 1 is in a ready state (a state capable of receiving external commands) or a busy state (a state incapable of receiving external commands). The signal DQ<7:0> is, for example, an 8-bit signal. The signal DQS is a data strobe signal for controlling an operation timing of the semiconductor memory device 1 related to the signal DQ<7:0>. For example, in single data rate, the signal DQS instructs the semiconductor memory device 1 to latch the signal DQ<7:0> as data on a falling edge and a rising edge of the signal DQS. In double data rate, the signal DQS is generated based on a falling edge and a rising edge of the signal/RE and output as data from the semiconductor memory device 1 with the signal DQ<7:0>. The signal/DQS is a complementary signal of the signal DQS.

The signal DQ<7:0> is transmitted and received between the semiconductor memory device 1 and the memory controller 2. The signal DQ<7:0> includes a command CMD, an address ADD, and data DAT. The command CMD includes, for example, a command causing the semiconductor memory device 1 to execute an erasing operation (erase command), a command causing the semiconductor memory device 1 to execute a write operation (write command), a command causing the semiconductor memory device to execute a read operation (read command), and the like. The data DAT includes read data and write data.

The memory controller 2 receives commands from the host device 4. The memory controller 2 controls the semiconductor memory device 1 based on the received commands. More specifically, the memory controller 2 writes data instructed to be written to the semiconductor memory device 1 based on a write command received from the host device 4. The memory controller 2 reads data instructed to be read by the host device 4 from the semiconductor memory device 1 based on a read command received from the host device 4. The memory controller 2 transmits the read data to the host device 4.

Examples of the host device 4 using the memory system 3 described above include a digital camera, a personal computer, and a server in a data center.

### 1.1.2 Memory Controller

As shown in FIG. 1, the memory controller 2 includes a central processing unit (CPU) 20, a built-in memory 21, a buffer memory 22, a NAND interface circuit (NAND I/F) 23, a host interface circuit (host I/F) 24, and an ECC circuit 25. For example, the memory controller 2 is implemented as a system-on-a-chip (SoC).

The CPU 20 controls an overall operation of the memory controller 2. For example, the CPU 20 issues a command for instructing the semiconductor memory device 1 to execute various operations such as the write operation, the read operation, and the erasing operation.

For example, the built-in memory 21 is a semiconductor memory such as a dynamic random access memory (DRAM). For example, the built-in memory 21 is used as a work area of the CPU 20. The built-in memory 21 stores, for example, firmware for managing the semiconductor memory device 1, various management tables, and the like.

The buffer memory 22 temporarily stores write data received from the host device 4, read data received from the semiconductor memory device 1 by the memory controller 2, and the like.

The NAND interface circuit 23 is connected to the semiconductor memory device 1 via the NAND bus. The NAND interface circuit 23 manages communication with the semiconductor memory device 1. For example, the NAND interface circuit 23 transmits the command CMD, the address ADD, and write data to the semiconductor memory device 1 under instruction of the CPU 20. The NAND interface circuit 23 receives read data from the semiconductor memory device 1.

The host interface circuit 24 is connected to the host device 4 via a host bus. The host interface circuit 24 manages communication between the memory controller 2 and the host device 4. For example, the host interface circuit 24 transmits commands and data received from the host device 4 to each of the CPU 20 and the buffer memory 22.

The ECC circuit 25 performs an error correction process related to data stored in the semiconductor memory device 1. More specifically, during writing of data, the ECC circuit 25 generates a parity of an error correction code and appends the parity of the error correction code to the write data. The error correction code is, for example, a hard-decision decoding code such as a Bose-Chaudhuri-Hocquenghem (BCH) code or a Reed-Solomon (RS) code, or a soft-decision decoding code such as a low-density parity-check (LDPC) code. During reading of data, the ECC circuit 25 may decode the error correction code and correct fail bits.

### 1.1.3 Semiconductor Memory Device

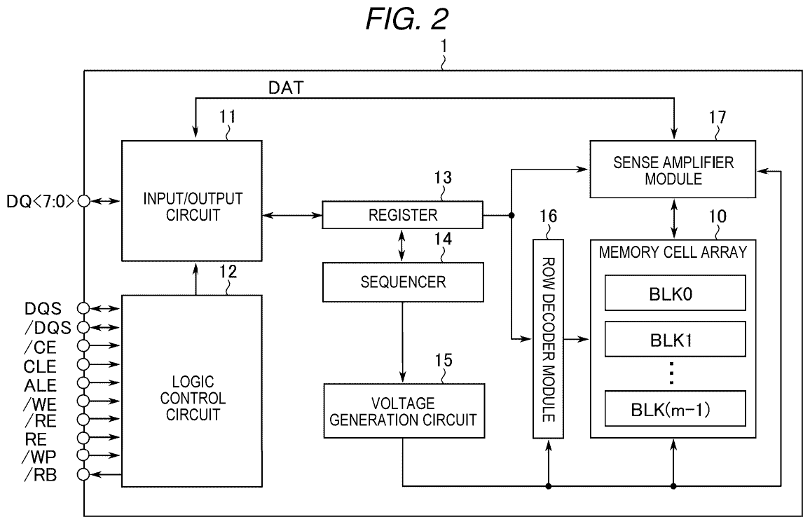

A configuration example of the semiconductor memory device 1 according to the embodiment will be described with reference to FIG. 2. FIG. 2 is a block diagram showing an example of a configuration of the semiconductor memory device according to the embodiment.

The semiconductor memory device 1 includes a memory cell array 10, an input/output circuit 11, a logic control circuit 12, a register 13, a sequencer 14, a voltage generation circuit 15, a row decoder module 16, and a sense amplifier module 17.

The memory cell array 10 includes a plurality of blocks BLK0 to BLK(m−1) (where, m is an integer equal to or greater than 1). In the following description, when the plurality of blocks BLK0 to BLK(m−1) are not distinguished from one another, each of the plurality of blocks BLK0 to BLK(m−1) is simply referred to as a block BLK. Each block BLK includes a plurality of memory cell transistors capable of storing data in a nonvolatile manner. Each block BLK is used as, for example, a data erasing unit. That is, data stored in the memory cell transistors in the same block BLK are collectively erased. Details of the configuration of the memory cell array 10 will be described below.

The input/output circuit 11 transmits and receives the signal DQ<7:0> to and from the memory controller 2. The input/output circuit 11 transmits the address ADD and the command CMD in the signal DQ<7:0> to the register 13. The input/output circuit 11 transmits and receives the data DAT to and from the sense amplifier module 17.

The logic control circuit 12 receives, for example, the signals /CE, CLE, ALE, ALE, /WE, /RE, RE, /WP, DQS, and /DQS from the memory controller 2, and controls the input/output circuit 11 based on the received signals. The logic control circuit 12 generates the signal /RB and transmits the signal/RB to the memory controller 2.

The register 13 stores the address ADD transmitted from the input/output circuit 11. The register 13 transmits the stored address ADD to the row decoder module 16 and the sense amplifier module 17.

The register 13 stores the command CMD transmitted from the input/output circuit 11. The register 13 transmits the stored command CMD to the sequencer 14.

The sequencer 14 receives the command CMD from the register 13. The sequencer 14 controls an overall operation of the semiconductor memory device 1 according to a sequence based on the received command CMD. For example, upon receiving each of the erase command, the write command, and the read command, the sequencer 14 instructs the voltage generation circuit 15 to generate a voltage to be used in the operation corresponding to the command.

The voltage generation circuit 15 generates a voltage used for the erasing operation, the write operation, the read operation, and the like, based on an instruction from the sequencer 14. The voltage generation circuit 15 supplies the generated voltage to the row decoder module 16, the sense amplifier module 17, the memory cell array 10, and the like.

The row decoder module 16 receives a block address in the address ADD from the register 13. The row decoder module 16 selects one of m blocks BLK based on the received block address. The row decoder module 16 applies, for example, the voltage supplied from the voltage generation circuit 15 to the selected block BLK.

The sense amplifier module 17 receives a column address in the address ADD from the register 13. The sense amplifier module 17 transmits the data DAT between the memory controller 2 and the memory cell array 10 based on the received column address. More specifically, the sense amplifier module 17 receives write data from the input/output circuit 11 during the write operation. Then, the sense amplifier module 17 transmits the received write data to the memory cell array 10. The sense amplifier module 17 senses a threshold voltage of the memory cell transistor to be read in the memory cell array 10 and generates read data during the read operation. The sense amplifier module 17 transmits the generated read data to the input/output circuit 11.

### 1.1.4 Circuit Configuration of Memory Cell Array

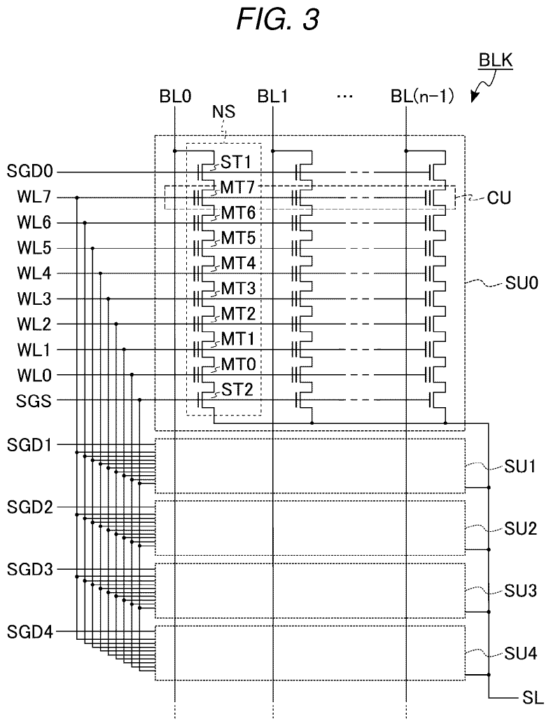

A circuit configuration of the memory cell array 10 of the semiconductor memory device 1 according to the embodiment will be described with reference to FIG. 3. FIG. 3 is a circuit diagram showing an example of a configuration of the memory cell array of the semiconductor memory device according to the embodiment.

For example, each block BLK includes five string units SU0 to SU4. Each of the string units SU0 to SU4 includes a plurality of NAND strings NS. In the following description, when the string units SU0 to SU4 are not distinguished from one another, each of the string units SU0 to SU4 is simply referred to as a string unit SU. The number of string units SU provided in each block BLK is not limited to five. The number of string units SU provided in each block BLK may be one to four, or six or more.

Each NAND string NS includes, for example, eight memory cell transistors MT0 to MT7 and select transistors ST1 and ST2. Each of the memory cell transistors MT0 to MT7 includes a gate and a charge storage layer. The memory cell transistors MT0 to MT7 are connected in series between the select transistors ST1 and ST2. In the following description, when the memory cell transistors MT0 to MT7 are not distinguished from one another, each of the memory cell transistors MT0 to MT7 is simply referred to as a memory cell transistor MT. When the select transistors ST1 and ST2 are not distinguished from one another, each of the select transistors ST1 and ST2 is simply referred to as a select transistor ST. The number of memory cell transistors MT provided in each NAND string NS is not limited to eight. The number of memory cell transistors MT provided in each NAND string NS may be 16, 32, 48, 64, 96, 128, and the like, and the number of memory cell transistors MT is not limited. The number of select transistors ST1 and ST2 may not be limited to one each, and may be any number.

The gates of the select transistors ST1 of the string units SU0 to SU4 in each block BLK are each connected to select gate lines SGD0 to SGD4. The gates of the select transistors ST2 of the string units SU in each block BLK are connected to the select gate line SGS. Although not shown, each block BLK may include, for example, five select gate lines SGS0 to SGS4. Here, the gates of the select transistors ST2 of the string units SU0 to SU4 may be each connected to the select gate lines SGS0 to SGS4 similarly to those of the select transistors ST1 of the string units SU0 to SU4. In the following description, when the select gate lines SGD0 to SGD4 are not distinguished from one another, each of the select gate lines SGD0 to SGD4 is simply referred to as a select gate line SGD.

The gates of memory cell transistors MT0 to MT7 in each block BLK are respectively connected to word lines WL0 to WL7. The number of word lines WL in each block BLK is not limited to eight, similarly to the number of memory cell transistors MT provided in each NAND string NS. The number of word lines WL in each block BLK may be 16, 32, 48, 64, 96, 128, and the like, and the number of word lines is not limited. In the following description, when the word lines WL0 to WL7 are not distinguished from one another, each of the word lines WL0 to WL7 is simply referred to as a word line WL.

According to the configuration described above, in each block BLK, the word lines WL and the select gate line SGS are connected to the string units SU0 to SU4. Meanwhile, in each block BLK, each select gate line SGD is connected to one corresponding string unit SU.

Among the NAND strings NS arranged in a matrix configuration in the memory cell array 10, the other end of the select transistor ST1 of the NAND strings NS in the same row is connected to one of n (n is an integer equal to or greater than 2) bit lines BL (BL0 to BL(n−1)). The bit lines BL are connected to the NAND strings NS in the same column across a plurality of blocks BLK.

The other end of the select transistor ST2 is connected to a source line SL. For example, the source line SL is shared by the plurality of blocks BLK.

For example, a set of memory cell transistors MT connected to a common word line WL in each string unit SU is referred to as a cell unit CU. A storage capacity of the cell unit CU including the plurality of memory cell transistors MT each storing 1-bit data is defined as “1-page data”, for example. The cell unit CU may have a storage capacity of 2-page data or more according to the number of bits of data that can be stored in each memory cell transistors MT.

### 1.1.5 Structure of Memory Cell Array

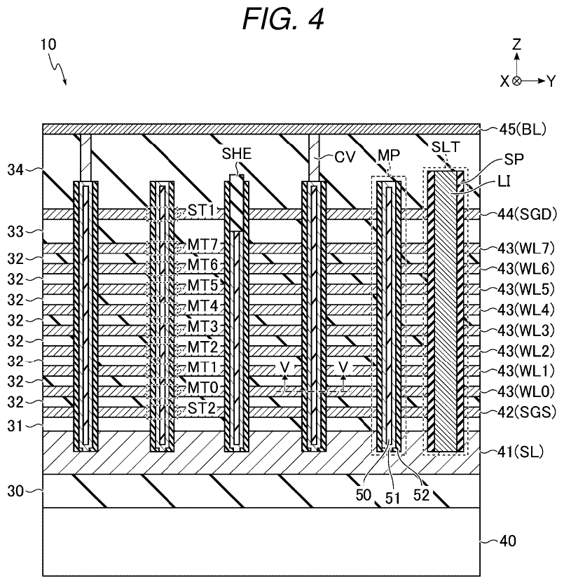

A structure of the memory cell array 10 of the semiconductor memory device 1 according to the embodiment will be described with reference to FIG. 4. FIG. 4 is a cross-sectional view showing an example of the structure of the memory cell array of the semiconductor memory device according to the embodiment. Note that, in the drawings described below, an X direction corresponds to an extending direction of the word line WL. A Y direction perpendicular to the X direction in the horizontal plane corresponds to an extending direction of the bit line BL. A Z direction orthogonal to the horizontal surface corresponds to a vertical direction relative to a surface of a semiconductor substrate used in formation of the semiconductor memory device 1.

The memory cell array 10 further includes a semiconductor substrate 40, conductor layers 41 to 45, and insulator layers 30 to 34.

The insulator layer 30 is provided on the semiconductor substrate 40. Although not shown in FIG. 4, the insulator layer 30 and the semiconductor substrate 40 include, for example, circuits such as the row decoder module 16 and the sense amplifier module 17. In the following description, one side of the semiconductor substrate 40 on which the memory cell array 10 is provided is regarded as an upper side.

The conductor layer 41 is provided on the insulator layer 30. For example, the conductor layer 41 is formed in a plate shape extending in an XY plane. The conductor layer 41 is used as the source line SL. The conductor layer 41 includes, for example, silicon doped with phosphorus.

The insulator layer 31 is provided on the conductor layer 41. The conductor layer 42 is provided on the insulator layer 31. For example, the conductor layer 42 is formed in a plate shape extending in the XY plane. The conductor layer 42 is used as the select gate line SGS. The conductor layer 42 includes, for example, tungsten.

Eight insulator layers 32 and eight conductor layers 43 are stacked on the conductor layer 42. The eight insulator layers 32 and the eight conductor layers 43 are stacked upward in the order of the insulator layer 32, the conductor layer 43, the insulator layer 32, . . . , the conductor layer 43, the insulator layer 32, and the conductor layer 43. For example, the conductor layer 43 is formed in a plate shape extending in the XY plane. A stack of the plurality of conductor layers 43 are used as the word lines WL0 to WL7 sequentially from the semiconductor substrate 40 side. The conductor layer 43 includes, for example, tungsten.

The insulator layer 33 is provided on the uppermost conductor layer 43. The conductor layer 44 is provided on the insulator layer 33. For example, the conductor layer 44 is formed in a plate shape extending in the XY plane. The conductor layer 44 is used as the select gate line SGD. The conductor layer 44 includes, for example, tungsten.

In the following description, each of the conductor layers 42 to 44 is simply referred to as a stacked wiring.

The insulator layer 34 is provided on the conductor layer 44. A plurality of conductor layers 45 are provided on the insulator layer 34. For example, each conductor layer 45 is formed in a line shape extending in the Y direction. In FIG. 4, only one conductor layer 45 among the plurality of conductor layers 45 is shown. Each conductor layer 45 is used as the bit line BL. The conductor layer 45 includes, for example, copper.

Each memory pillar MP extends in the Z direction and penetrates the insulator layers 31 to 33 and the conductor layers 42 to 44. A bottom portion of the memory pillar MP is in contact with the conductor layer 41. An intersection between the memory pillar MP and the conductor layer 42 functions as the select transistor ST2. An intersection between the memory pillar MP and one conductor layer 43 functions as one memory cell transistor MT. An intersection between the memory pillar MP and the conductor layer 44 functions as the select transistor ST1.

Each memory pillar MP includes, for example, a core member 50, a semiconductor layer 51, and a stacked film 52. The core member 50 extends in the Z direction. An upper end of the core member 50 is positioned, for example, above the conductor layer 44. A lower end of the core member 50 is positioned, for example, below the conductor layer 42. The semiconductor layer 51 covers a periphery of the core member 50. At a lower portion of the memory pillar MP, a portion of the semiconductor layer 51 is in contact with the conductor layer 41. The stacked film 52 covers a side surface and a bottom surface of the semiconductor layer 51 except for a portion at which the semiconductor layer 51 and the conductor layer 41 are in contact with each other. The core member 50 includes, for example, an insulator such as silicon oxide. The semiconductor layer 51 includes, for example, silicon.

A columnar contact CV is provided on an upper surface of the semiconductor layer 51 in the memory pillar MP. In the region shown in the drawing, one contact CV corresponding to one memory pillar MP among three memory pillars MP is shown. In a memory region MR, the memory pillar MP not overlapping with a member SHE and not connected to the contact CV is connected with a contact CV in a region not shown in the drawings.

An upper surface of the contact CV is electrically connected to one conductor layer 45. The contacts CV are provided such that one contact CV is connected to one conductor layer 45 in each of spaces sectioned by members SLT and SHE. That is, each memory pillar MP in each string unit SU is electrically connected to one of the conductor layers 45.

The member SLT is provided with, for example, a portion provided in the XZ plane. For example, the member SLT divides the conductor layers 42 to 44. The member SLT includes a contact LI and a spacer SP. The contact LI is, for example, a conductor provided with a portion extending in the X direction. The spacer SP is, for example, an insulator provided on a side surface of the contact LI. The spacer SP separates the contact LI from the stacked wiring adjacent to the contact LI in the Y direction. As a result, the contact LI is electrically insulated from the stacked wiring adjacent to the contact LI in the Y direction. The contact LI may be an insulator. Then, the contact LI and the spacer SP may be integrally formed.

The member SHE has, for example, a portion provided in the XZ plane. The member SHE divides, for example, the conductor layer 44. A lower surface of the member SHE is positioned, for example, between the uppermost conductor layer 43 and the conductor layer 44. The member SHE includes, for example, an insulator such as silicon oxide.

### 1.1.6 Structure of Memory Pillar

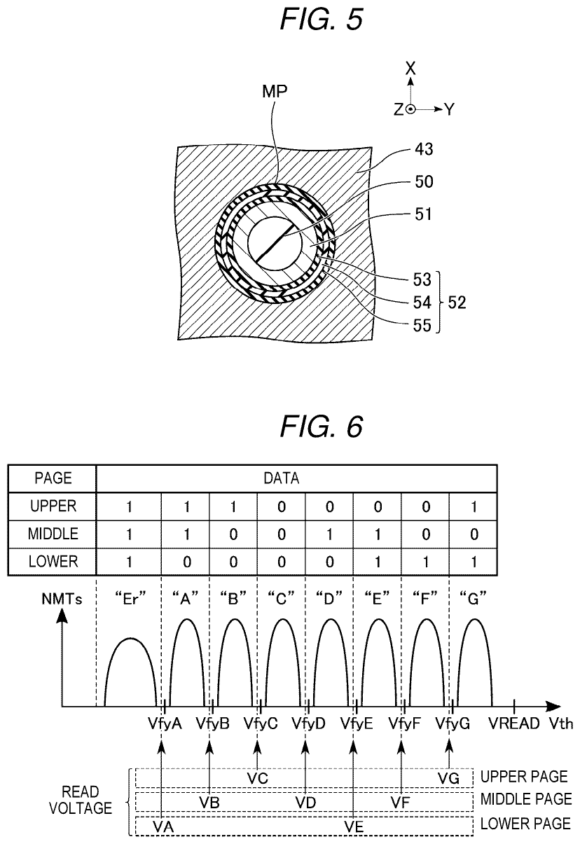

A structure of the memory pillar MP in the semiconductor memory device 1 according to the embodiment will be described with reference to FIG. 5. FIG. 5 is a cross-sectional view along a V-V line of FIG. 4, showing an example of a cross-sectional structure of the memory pillar in the memory cell array of the semiconductor memory device according to the embodiment.

The stacked film 52 includes, for example, a tunnel insulating film 53, an insulating film 54, and a block insulating film 55.

In the cross section including the conductor layer 43, the core member 50 is provided in a center portion of the memory pillar MP. The core member 50 has, for example, a circular shape in the XY plane. The semiconductor layer 51 surrounds a side surface of the core member 50. The tunnel insulating film 53 surrounds a side surface of the semiconductor layer 51. The insulating film 54 surrounds a side surface of the tunnel insulating film 53. The block insulating film 55 surrounds a side surface of the insulating film 54. The conductor layer 43 surrounds a side surface of the block insulating film 55. Each of the tunnel insulating film 53 and the block insulating film 55 includes, for example, silicon oxide. The insulating film 54 includes, for example, silicon nitride.

The memory pillar MP having the configuration described above has, for example, a circular shape in the XY plane.

The semiconductor layer 51 functions as a channel of the memory cell transistors MT0 to MT7 and the select transistors ST1 and ST2. That is, the semiconductor layer 51 functions as a channel of the memory pillar MP and a channel of the NAND string NS. The insulating film 54 is used as a charge storage layer of the memory cell transistor MT. The semiconductor memory device 1 allows a current to flow into the memory pillar MP between the bit line BL and the source line SL by turning on the memory cell transistors MT0 to MT7 and the select transistor ST1 and ST2.

### 1.1.7 Threshold Voltage Distribution of Memory Cell Transistor

A threshold voltage distribution of the memory cell transistor MT in the semiconductor memory device 1 according to the embodiment will be described with reference to FIG. 6. FIG. 6 is a schematic diagram showing an example of the threshold voltage distribution of the memory cell transistor in the memory cell array of the semiconductor memory device according to the embodiment. In the threshold voltage distribution shown in FIG. 6, a horizontal axis corresponds to a threshold voltage of the memory cell transistor MT. A vertical axis corresponds to the number of memory cell transistors MT. In FIG. 6, the threshold voltage and the number of memory cell transistors MT are each shown as a voltage Vth and a value NMT.

In the semiconductor memory device 1 according to the embodiment, eight states are formed in each block BLK, for example, by threshold voltages of the plurality of memory cell transistors MT. Hereinafter, the eight states are referred to as “Er” state, “A” state, “B” state, “C” state, “D” state, “E” state, “F” state, and “G” state sequentially from the lowest threshold voltage. For example, the number of memory cell transistors MT in the “Er” state to “G” states is approximately the same for each state.

The “Er” state corresponds, for example, to a data-erased state. A threshold voltage of the memory cell transistor MT in the “Er” state is lower than a voltage VA.

The “A”, “B”, “C”, “D”, “E”, “F”, and “G” states correspond to a data-written state. A threshold voltage of the memory cell transistor MT in the “A” state is equal to or higher than the voltage VA and lower than a voltage VB (VB>VA). A threshold voltage of the memory cell transistor MT in the “B” state is equal to or higher than the voltage VB and lower than a voltage VC (VC>VB). A threshold voltage of the memory cell transistor MT in the “C” state is equal to or higher than the voltage VC and lower than a voltage VD (VD>VC). A threshold voltage of the memory cell transistor MT in the “D” state is equal to or higher than the voltage VD and lower than a voltage VE (VE>VD). A threshold voltage of the memory cell transistor MT in the “E” state is equal to or higher than the voltage VE and lower than a voltage VF (VF>VE). A threshold voltage of the memory cell transistor MT in the “F” state is equal to or higher than the voltage VF and lower than a voltage VG (VG>VF). A threshold voltage of the memory cell transistor MT in the “G” state is equal to or higher than the voltage VG and lower than a voltage VREAD (VREAD>VG). The voltage VREAD is a voltage that turns on the memory cell transistor MT when applied to the gate (word line WL) of the memory cell transistor MT regardless of whether the memory cell transistor MT is in any of the “Er” to “G” states.

The memory cell transistor MT is turned on when the voltage applied to the gate (word line WL) is higher than the threshold voltage of the memory cell transistor MT. The memory cell transistor MT is turned off when the voltage applied to the gate (word line WL) is equal to or lower than the threshold voltage of the memory cell transistor MT.

Different 3-bit data are assigned to each of the threshold voltage distributions of the eight types of memory cell transistors MT described above. Hereinafter, an example of data assignment with respect to the threshold voltage distribution is listed. Data assigned to each state are shown below in the order of “upper bit, middle bit, and lower bit” corresponding to the state.
“Er” state: “1, 1, 1” data,
“A” state: “1, 1, 0” data,
“B” state: “1, 0, 0” data,
“C” state: “0, 0, 0” data,
“D” state: “0, 1, 0” data,
“E” state: “0, 1, 1” data,
“F” state: “0, 0, 1” data, and
“G” state: “1, 0, 1” data.

When such data assignment is applied, one page data configured with low-order bits (lower page data) is determined by read operations using each of the voltages VA and VE. One page data configured with middle bits (middle page data) are determined by read operations using each of the voltages VB, VD, and VF. One page data configured with upper bits (upper page data) are determined by read operations using each of the voltages VC and VG.

A verification voltage used in determination of the threshold voltage of the memory cell transistor MT is set between each of adjacent states. More specifically, a voltage VfyA is set as a verification voltage between the “Er” state and the “A” state. The voltage VfyA is, for example, higher than the voltage VA. A voltage VfyB is set as a verification voltage between the “A” state and the “B” state. The voltage VfyB is, for example, higher than the voltage VB. A voltage VfyC is set as a verification voltage between the “B” state and the “C” state. The voltage VfyC is, for example, higher than the voltage VC. A voltage VfyD is set as a verification voltage between the “C” state and the “D” state. The voltage VfyD is, for example, higher than the voltage VD. A voltage VfyE is set as a verification voltage between the “D” state and the “E” state. A voltage VfyE is, for example, higher than a voltage VE. A voltage VfyF is set as a verification voltage between the “E” state and the “F” state. The voltage VfyF is, for example, higher than the voltage VF. A voltage VfyG is set as a verification voltage between the “F” state and the “G” state. The voltage VfyG is, for example, higher than the voltage VG.

In the description of the semiconductor memory device 1 according to the embodiment, an example in which each memory cell transistor MT stores 3-bit data is described, but the embodiments are not limited thereto. The semiconductor memory device 1 may be configured such that, for example, each memory cell transistor MT stores 2-bit data or 4-bit data or more.

### 1.1.8 Sense Amplifier Module

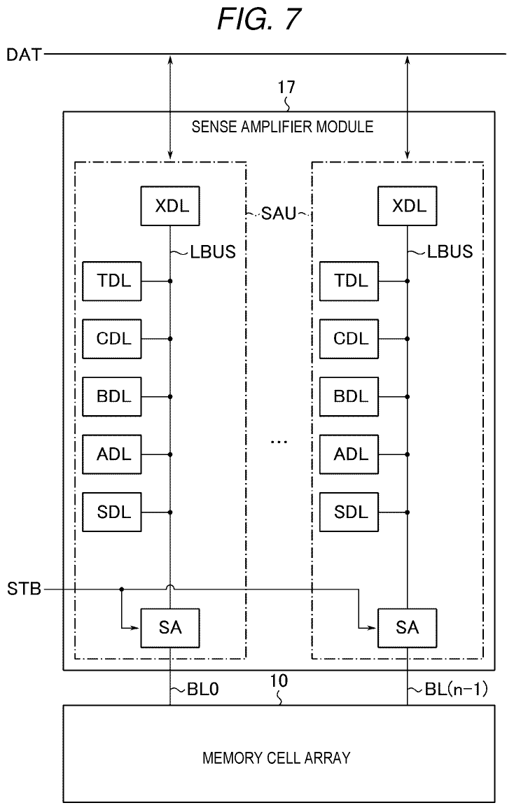

A configuration of the sense amplifier module 17 in the semiconductor memory device 1 according to the embodiment will be described with reference to FIG. 7. FIG. 7 is a block diagram showing an example of the configuration of the sense amplifier module of the semiconductor memory device according to the embodiment.

The sense amplifier module 17 includes a plurality of sense amplifier units SAU connected to each of the plurality of bit lines BL.

Each sense amplifier unit SAU includes, for example, latch circuits SDL, ADL, BDL, CDL, TDL, and XDL, and a sensing circuit SA. The latch circuits SDL, ADL, BDL, CDL, TDL, and XDL and the sensing circuit SA are connected to one another via a bus LBUS. As a result, the latch circuits SDL, ADL, BDL, CDL, TDL, and XDL and the sensing circuit SA are connected to transmit and receive data to and from one another via the bus LBUS.

For example, the latch circuit XDL is used for transmitting and receiving the data DAT between the sense amplifier unit SAU and the input/output circuit 11.

The latch circuits SDL, ADL, BDL, CDL, and TDL temporarily store, for example, write data or read data.

During the read operation, the sensing circuit SA senses a current flowing in the corresponding bit line BL or a voltage of the bit line BL, and determines whether read data is “0” or “1”. Hereinafter, an example in which the sensing circuit SA senses the current flowing in the bit line BL will be described. The sense amplifier unit SAU determines read data, for example, at a timing corresponding to a signal STB generated by the sequencer 14. During the write operation, the sensing circuit SA applies a voltage to the bit line BL based on write data. For example, the sensing circuit SA controls the bit line BL according to stored data of the latch circuit SDL.

The configuration of the sense amplifier unit SAU is not limited to the above description, and various changes are possible. For example, the number of latch circuits provided by the sense amplifier unit SAU may be designed according to the number of bits of data stored by the memory cell transistor MT.

### 1.1.9 Sensing Circuit

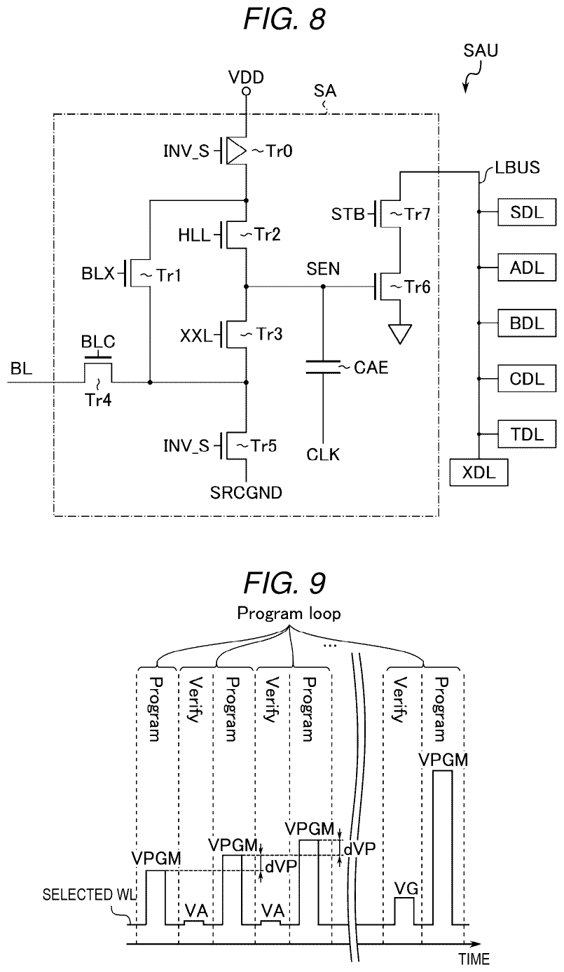

An example of a configuration of the sensing circuit SA of the sense amplifier unit SAU in the sense amplifier module 17 will be described with reference to FIG. 8. FIG. 8 is a circuit diagram showing an example of a circuit configuration of the sense amplifier circuit provided in the semiconductor memory device according to the embodiment. In FIG. 8, the circuit configuration of the sensing circuit SA is shown with other configurations of the sense amplifier unit SAU.

The sensing circuit SA includes, for example, transistors Tr0 to Tr7 and a capacitor CAE. The transistor Tr0 is, for example, a P-type metal-oxide-semiconductor field effect transistor (MOSFET). The transistors Tr1 to Tr7 are, for example, N-type MOSFETs.

For example, a voltage VDD is applied to a source of the transistor Tr0. A drain of the transistor Tr0 is connected to the transistors Tr1 and Tr2. A gate of the transistor Tr0 is, for example, connected to a node INV_S in the latch circuit SDL.

A drain of the transistor Tr1 is connected to the drain of the transistor Tr0. A source of the transistor Tr1 is connected to the transistors Tr3, Tr4, and Tr5. A signal BLX is input to a gate of the transistor Tr1.

A drain of the transistor Tr2 is connected to the drain of the transistor Tr0 and the drain of the transistor Tr1. A source of the transistor Tr2 is connected to a node SEN. A signal HLL is input to a gate of the transistor Tr2.

A drain of the transistor Tr3 is connected to the node SEN. A source of the transistor Tr3 is connected to the source of the transistor Tr1. A signal XXL is input to a gate of the transistor Tr3.

A drain of the transistor Tr4 is connected to the source of the transistor Tr1 and the source of the transistor Tr3. A signal BLC is input to a gate of the transistor Tr4. A source of the transistor Tr4 is connected to the corresponding bit line BL. The transistor Tr4 functions as a clamp transistor that clamps a voltage of the bit line BL according to the signal BLC.

A drain of the transistor Tr5 is connected to the source of the transistor Tr1, the source of the transistor Tr3, and the drain of the transistor Tr4. A source of the transistor Tr5 is connected to a node SRCGND. For example, a voltage VSS is applied to the node SRCGND. The voltage VSS is the ground voltage. A gate of the transistor Tr5 is connected to the node INV_S, for example.

A source of the transistor Tr6 is grounded. A gate of the transistor Tr6 is connected to the node SEN. The transistor Tr6 functions as a sensing transistor that senses a voltage of the node SEN.

A drain of the transistor Tr7 is connected to the bus LBUS. A source of the transistor Tr7 is connected to a drain of the transistor Tr6. The signal STB is input to a gate of the transistor Tr7.

One electrode of the capacitor CAE is connected to the node SEN. A clock signal CLK is input to the other electrode of the capacitor CAE.

Each of the signals BLX, HLL, XXL, BLC, and STB and the clock signal CLK is generated by, for example, the sequencer 14.

During the read operation, for example, when the node INV_S is set to a “Low (L)” level, the transistor Tr0 is turned on. For example, when the signals BLX and BLC are set to the “H” level, the transistors Tr1 and Tr4 are turned on. As a result, the bit line BL is precharged to a voltage corresponding to the signal BLC via the transistors Tr0, Tr1, and Tr4. For example, when the signal HLL is set to the “H” level, the transistor Tr2 is turned on. As a result, the node SEN is precharged to the voltage VDD.

For example, when the signal HLL is changed from the “H” level to the “L” level, the transistor Tr2 is changed from the on state to the off state, and next, when the signal XXL is set to the “H” level, the transistor Tr3 is turned on. When the memory cell transistor MT to be read is turned on, a current flows from the bit line BL to the source line SL, thereby lowering the voltage of the node SEN. When the voltage of the node SEN is lower than the threshold voltage of the transistor Tr6, the transistor Tr6 is turned off. Meanwhile, when the memory cell transistor MT to be read is turned off, a current does not flow from the bit line BL to the source line SL, and the voltage of the node SEN remains substantially the same. The transistor Tr6 is turned on. Hereinafter, the memory cell transistor MT to be read is also referred to as a selected memory cell transistor MT. In the following description, the memory cell transistor MT not to be read is also referred to as a non-selected memory cell transistor MT. The selected memory cell transistor MT in the on state is also referred to as an on cell. In the following description, the selected memory cell transistor MT not in the on state is also referred to as an off cell.

For example, when the signal STB is changed from the “L” level to the “H” level, the transistor Tr7 is changed from the off state to the on state. As a result, voltages corresponding to the on state and the off state of the transistor Tr6 is transmitted through the bus LBUS. When the transistor Tr6 is turned off, the bus LBUS is set to the “H” level. When the transistor Tr6 is turned on, the bus LBUS is set to the “L” level. When the bus LBUS is set to the “H” level, the sense amplifier unit SAU stores data of “1”, for example, in the latch circuit SDL. When the bus LBUS is set to the “L” level, the sense amplifier unit SAU stores data of “0”, for example, in the latch circuit SDL. Data stored in the latch circuit SDL is transmitted, for example, to the latch circuit ADL, BDL, CDL, or TDL.

### 1.2 Operation

Next, operations using the semiconductor memory device 1 according to the embodiment will be described.

In the following description, the word line WL selected based on the address ADD is referred to as a selected word line WL or a selected WL. The word line WL that is not selected is referred to as a non-selected word line WL or a non-selected WL. The memory cell transistor MT connected to the selected word line WL is referred to as a selected memory cell transistor MT.

### 1.2.1 Overview of Write Operation

An overview of the write operation of the semiconductor memory device 1 according to the embodiment will be described with reference to FIG. 9. FIG. 9 is a timing chart showing an overview of the write operation of the semiconductor memory device according to the embodiment.

The semiconductor memory device 1 repeatedly executes a loop operation (Program loop) during the write operation. FIG. 9 shows a change in a voltage of the selected word line WL according to an increase in the number of execution of the loop operation during the write operation. In the following description, the number of execution of the loop operation is simply referred to as a loop count.

Each loop operation includes a verification operation (Verify) and a program operation (Program). The semiconductor memory device 1 raises a threshold voltage of the memory cell transistor MT to a target voltage (hereinafter also referred to as a target level) by repeatedly executing the loop operation.

In a first loop operation, for example, the verification operation is not executed, and only the program operation is executed. In second and subsequent loop operations, for example, the verification operation is executed and then the program operation is executed.

The program operation is an operation that may raise the threshold voltage of the memory cell transistor MT. In the program operation, a plurality of selected memory cell transistors MT are set as the memory cell transistors MT to be programmed or the memory cell transistors MT inhibited from programming based on write data stored in the associated sense amplifier unit SAU. When the threshold voltage of the selected memory cell transistor MT did not reach the target threshold voltage, the selected memory cell transistor MT is set as the memory cell transistor MT to be programmed. Meanwhile, when the threshold voltage of the selected memory cell transistor MT has reached the target threshold voltage, the selected memory cell transistor MT is set as the memory cell transistor MT inhibited from programming.

In the program operation, a voltage VPGM (write voltage) is applied to the selected word line WL. The voltage VPGM is a voltage that raises the threshold voltage of the selected memory cell transistor MT. The voltage VPGM, for example, increases according to an increase in the loop count. In the example of FIG. 9, each time the loop count increases, the voltage VPGM increases by a voltage dVP. When the voltage VPGM is applied to the selected word line WL, the threshold voltage of the memory cell transistor MT to be programmed rises. Meanwhile, the threshold voltage of the selected memory cell transistor MT set as the memory cell transistor MT inhibited from programming is maintained.

Hereinafter, an operation of raising the threshold voltage of the memory cell transistor MT is referred to as a program operation of “0”. An operation of maintaining the threshold voltage of the memory cell transistor MT is referred to as a program operation of “1”.

When the program operation is completed, the sequencer 14 executes, for example, the verification operation.

The verification operation is a read operation of checking whether the threshold voltage of the selected memory cell transistor MT has reached the target threshold voltage. For example, in each loop operation, the sequencer 14 executes the read operation using a predetermined verification voltage for the memory cell transistor MT to be programmed.

In the example of FIG. 9, an example using one verification voltage in each verification operation is shown, but the embodiments are not limited thereto. As described below, a plurality of verification voltages may be used for each verification operation. Here, the sequencer 14 executes, for example, read operations using a plurality of verification voltages sequentially.

In the verification operation, the sense amplifier unit SAU determines whether the threshold voltage of the selected memory cell transistor MT is higher than the verification voltage applied to the selected word line WL based on the voltage of the bit line BL. Each sense amplifier unit SAU determines “verify pass” for the selected memory cell transistor MT when the threshold voltage of the selected memory cell transistor MT is determined to be higher than the verification voltage. Meanwhile, each sense amplifier unit SAU determines “verify fail” for the selected memory cell transistor MT when the threshold voltage of the selected memory cell transistor MT is equal to or lower than the verification voltage. Each sense amplifier unit SAU stores the verification result as described above in any latch circuit in the sense amplifier unit SAU. When the verification operation is completed, the sequencer 14 sets each selected memory cell transistor MT as either the memory cell transistor MT to be programmed or the memory cell transistor MT inhibited from programming based on the result of the verification operation, and starts the next loop operation.

### 1.2.2 Program Operation

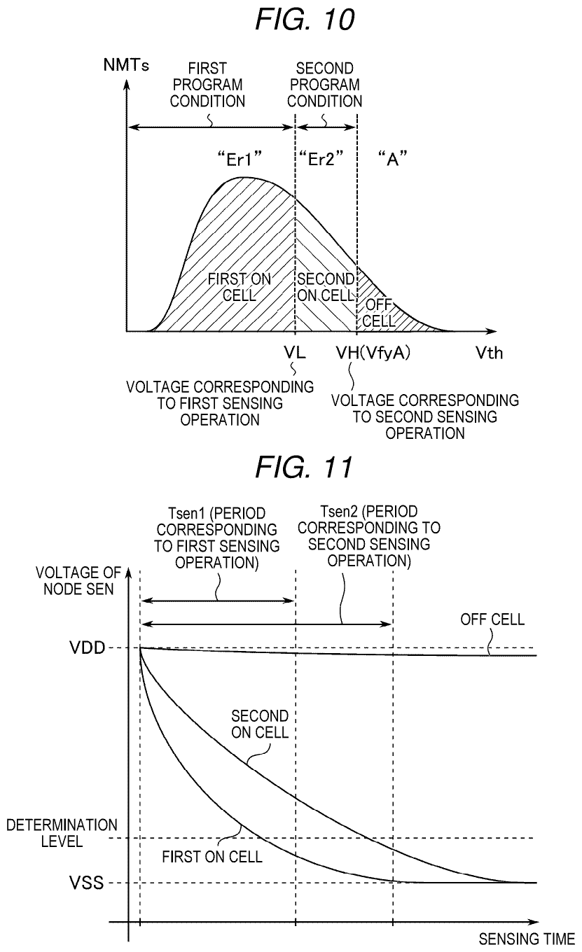

An example of the program operation in the embodiment will be described with reference to FIG. 10. FIG. 10 is a diagram showing selection of the program operation during the write operation using the semiconductor memory device according to the embodiment. Hereinafter, in a description of the selection of the program operation, for simplicity, an example of the threshold voltage distribution during a process in which the memory cell transistor MT transitions from the “Er” state to the “A” state is shown.

In the embodiment, in the program operation of “0”, either a first programming condition having a relatively large amount of increase in the threshold voltage, or a second programming condition having a smaller amount of increase in the threshold voltage than the first programming condition is applied according to a difference between the target level and the threshold voltage of the memory cell transistor MT.

For example, when it is assumed that the threshold voltage of the memory cell transistor MT is sufficiently lower than the target level and will not reach the target level in the next program operation, the first programming condition with the relatively large amount of increase in the threshold voltage is applied. When the threshold voltage of the memory cell transistor MT is relatively close to the target level and it is assumed that the threshold voltage will significantly exceed the target level when the first programming condition is applied in the next program operation, the second programming condition is applied.

When the threshold voltage of the memory cell transistor MT is equal to or higher than the voltage VH (voltage VfyA in FIG. 10) (when the memory cell transistor MT is in the “A” state), the program operation of “1” is executed on the memory cell transistor MT, and when the threshold voltage is lower than the voltage VH, the program operation of “0” is executed. The voltage VH is a voltage used for a second sensing operation (a voltage corresponding to a second sensing operation) to be described below.

For example, a predetermined voltage VL lower than the voltage VH may be set to determine whether to apply the first programming condition or the second programming condition in the program operation of “0”. That is, when the threshold voltage of the memory cell transistor MT is lower than the voltage VL (when the memory cell transistor MT is in an “Er1” state), the first programming condition is applied to the memory cell transistor MT. When the threshold voltage of the memory cell transistor MT is equal to or higher than the voltage VL and lower than the voltage VH (when the memory cell transistor MT is in an “Er2” state), the second programming condition is applied to the memory cell transistor MT in the next program operation. The voltage VL is a voltage used for a first sensing operation (a voltage corresponding to a first sensing operation) to be described below.

### 1.2.3 Verification Operation

Next, an example of the verification operation in the embodiment will be described with reference to FIG. 11. In the verification operation, the first sensing operation and the second sensing operation to be described below are executed. FIG. 11 is a diagram showing the first sensing operation and the second sensing operation in the verification operation using the semiconductor memory device according to the embodiment.

In the verification operation, the semiconductor memory device 1 determines whether to execute the program operation of “0” or the program operation of “1” for the next program operation. The semiconductor memory device 1 determines whether to apply the first programming condition or the second programming condition when executing the program operation of “0”.

In the following description, the verification operations includes an operation of determining whether to apply the first programming condition of the program operation of “0” for the next program operation, referred to herein as the first sensing operation. The verification operation includes an operation of determining whether to apply the program operation of “1” or to apply the second programming condition of the program operation of “0” to the memory cell transistor MT determined not to apply the first programming condition of the program operation of “O” in the next program operation, referred to herein as the second sensing operation.

That is, the first sensing operation corresponds to an operation of determining whether the threshold voltage of the memory cell transistor MT has reached the voltage VL. The second sensing operation corresponds to an operation of determining whether the threshold voltage of the memory cell transistor MT of which the threshold voltage has reached the voltage VL also reached the voltage VH.

As described below, for example, in the verification operation, the semiconductor memory device 1 transmits a charge of the node SEN to the bit line BL in two separate periods. A first period (sensing period Tsen1 in FIG. 11) corresponds to the first sensing operation. A second period (sensing period Tsen2 in FIG. 11) corresponds to the second sensing operation.

FIG. 11 shows voltages of the node SEN corresponding to the memory cell transistor MT as a target of the program operation of “1” (off cell), the memory cell transistor MT as a target of the program operation of “0” applying the first programming condition (first on cell), and the memory cell transistor MT as a target of the program operation of “0” applying the second programming condition (second on cell).

When the charge of the node SEN is transmitted to the bit line BL during the sensing period, the voltage of the node SEN decreases. Here, a decrease rate of the voltage of the node SEN varies depending on the threshold voltage of the memory cell transistor MT. For example, when the threshold voltage is lower than the voltage VL (when the memory cell transistor MT is the first on cell), the memory cell transistor MT is set to a strong on-state. As a result, the voltage of the node SEN decreases rapidly. When the threshold voltage is equal to or higher than the voltage VL and lower than the voltage VH (when the memory cell transistor MT is the second on cell), the memory cell transistor MT is set to a weak on-state. As a result, the voltage of the node SEN decreases gradually. When the threshold voltage is equal to or higher than the voltage VH (when the memory cell transistor MT is the off cell), the memory cell transistor MT is set to the off-state. As a result, the voltage of the node SEN hardly decreases at all.

Based on the relationship described above, a length of the sensing period Tsen1 is set such that the voltage of the node SEN corresponding to the memory cell transistor MT having a threshold voltage lower than the voltage VL falls below a predetermined determination level, and the voltage of the node SEN corresponding to the memory cell transistor MT having a threshold voltage equal to or higher than the voltage VL exceeds the determination level. Based on the relationship described above, a length of the sensing period Tsen2 is set such that the voltage of the node SEN corresponding to the memory cell transistor MT having a threshold voltage lower than the voltage VH falls below the determination level, and the voltage of the node SEN corresponding to the memory cell transistor MT having a threshold voltage equal to or higher than the voltage VH exceeds the determination level.

The sense amplifier module 17 determines whether the voltage of the node SEN falls below the determination level after the sensing period Tsen1. As a result, whether the memory cell transistor MT falls below the voltage VL (whether to apply the program operation of “0” of the first programming condition) is determined. The sense amplifier module 17 determines whether the voltage of the node SEN falls below the determination level after the sensing period Tsen2. As a result, whether the memory cell transistor MT determined to be equal to or higher than the voltage VL by the first sensing operation falls below the voltage VH (whether to apply the program operation of “0” of the second programming condition or apply the program operation of “1”) is determined.

### 1.2.4 Timing Chart

Next, an example of a voltage of each wiring of the verification operation and the program operation in the loop operation will be described using a timing chart.

### 1.2.4.1 Verification Operation

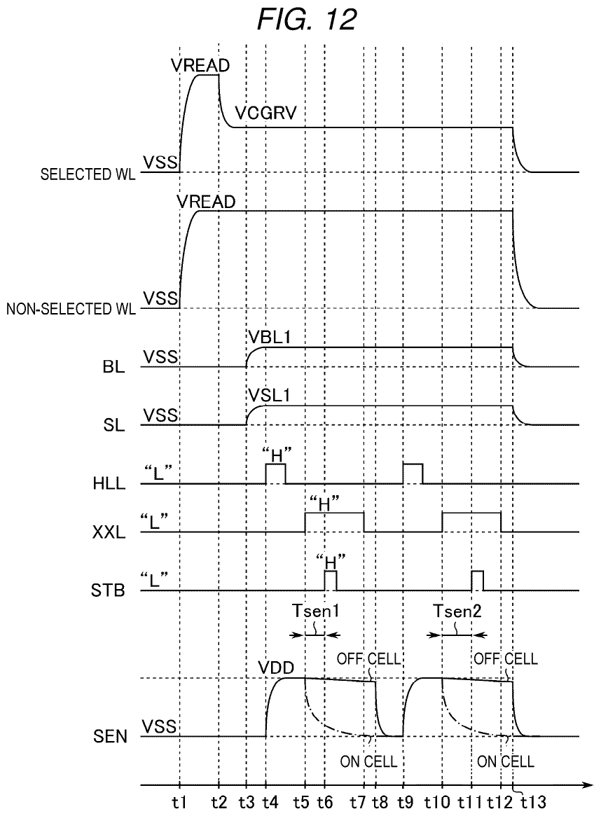

Examples of voltages of each wiring during the verification operation will be described with reference to FIG. 12. FIG. 12 is a timing chart of the verification operation during the write operation using the semiconductor memory device according to the embodiment. FIG. 12 shows an example of a timing chart of the verification operation for one target page.

At a time t1, the row decoder module 16 applies the voltage VREAD to the selected word line WL and the non-selected word line WL.

At a time t2, the row decoder module 16 applies a voltage VCGRV to the selected word line WL. The voltage VCGRV is a voltage set according to the verification voltage.

At a time t3, the sense amplifier module 17 applies a voltage VBL1 to the bit line BL. That is, the bit line BL is precharged. The voltage generation circuit 15 applies a voltage VSL1 to the source line SL.

At a time t4, the sequencer 14 changes the signal HLL from the “L” level to the “H” level and turns the transistor Tr2 on. The sequencer 14 maintains the signal HLL at the “H” level voltage for a predetermined period. As a result, the voltage VDD is precharged to the node SEN in the sense amplifier unit SAU.

At a time t5, the sequencer 14 changes the signal XXL from the “L” level to the “H” level and turns the transistor Tr3 on. Then, in the sensing period Tsen1 from the time t5 to a time t6, it is determined whether the threshold voltage is lower than the read voltage VL. That is, the first sensing operation is executed. More specifically, when the threshold voltage of the selected memory cell transistor MT is equal to or higher than the read voltage VL (is an off cell or a second on cell), at the time t6, the voltage of the node SEN remains at the “H” level voltage that turns the transistor Tr6 on. When the threshold voltage of the selected memory cell transistor MT is lower than the read voltage VL (is a first on cell), at the time t6, the voltage of the node SEN is lowered to the “L” level voltage that turns the transistor Tr6 off.

At the time t6, the sequencer 14 changes the voltage of the signal STB from the “L” level to the “H” level. The sequencer 14 maintains the signal STB at the “H” level voltage for a predetermined period. As a result, the transistor Tr7 is turned on in the sense amplifier unit SAU. As a result, when the transistor Tr6 is in the off state, the voltage of the bus LBUS is set to the “H” level. Meanwhile, when the transistor Tr6 is in the on state, the voltage of the bus LBUS is set to the “L” level. When the bus LBUS is at the “H” level, for example, data of “1” is stored in the latch circuit ADL. When the bus LBUS is at the “L” level, data of “0” is stored in the latch circuit ADL.

At a time t7, the sequencer 14 changes the signal XXL from the “H” level to the “L” level and turns the transistor Tr3 off.

At a time t8, the voltage of the node SEN is set to the voltage VSS.

At times t9 to t13, an operation equivalent to the operations at the times t4 to t8 is executed except that the sensing period is the sensing period Tsen2 instead of the sensing period Tsen1. As a result, it is determined whether the threshold voltage is lower than the read voltage VH. That is, the second sensing operation is executed.

As described above, the verification operation including the first sensing operation and the second sensing operation is executed.

### 1.2.4.2 Program Operation

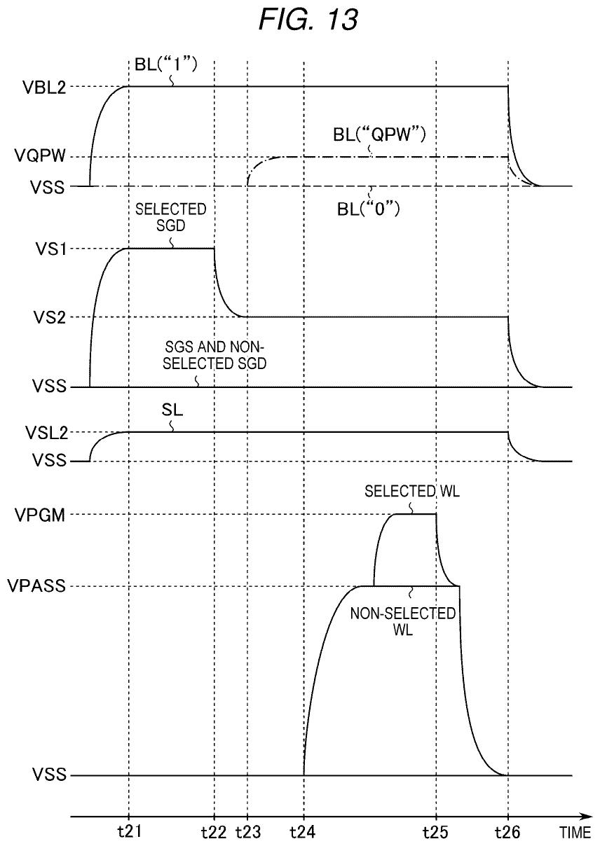

Examples of voltages of each wiring during the program operation will be described with reference to FIG. 13. FIG. 13 is a timing chart of the program operation during the write operation using the semiconductor memory device according to the embodiment. Regarding the voltage of the bit line BL shown in an upper portion of FIG. 13, a solid line corresponds to the bit line BL corresponding to the memory cell transistor MT targeted by the program operation of “1” (hereinafter referred to as a bit line BL (“1”)). A dashed line corresponds to the bit line BL corresponding to the memory cell transistor MT targeted by the program operation of “0” applying the first programming condition (hereinafter referred to as a bit line BL (“0”)). A single dotted line corresponds to the bit line BL corresponding to the memory cell transistor MT targeted by the program operation of “0” applying the second programming condition (hereinafter referred to as a bit line BL (“QPW”)).

At a time t21, the sense amplifier module 17 performs BL precharge. More specifically, the sense amplifier module 17 applies a voltage VBL2 to the bit line BL (“1”). Meanwhile, the sense amplifier module 17 applies the voltage VSS to the bit line BL (“0”) and the bit line BL (“QPW”).

The row decoder module 16 selects any block BLK and further selects any string unit SU. Then, the row decoder module 16 applies a voltage VS1 to the select gate line SGD in the selected string unit SU. The voltage VS1 is a voltage that turns the select transistor ST1 on. The row decoder module 16 applies the voltage VSS to the select gate line SGD of the non-selected string unit SU and turns the corresponding select transistor ST1 off. The row decoder module 16 applies the voltage VSS to the select gate line SGS and turns the select transistor ST2 off.

A voltage VSL2 (>VSS) is applied to the source line SL, for example, via a source line driver not shown in the drawing.

As a result, the voltage VBL2 is applied to a channel of the NAND string NS corresponding to the bit line BL (“1”), and the voltage VSS is applied to channels of the NAND strings NS corresponding to the bit lines BL (“0”) and BL (“QPW”).

At a time t22, the row decoder module 16 lowers the voltage applied to the select gate line SGD of the selected string unit SU from the voltage VS1 to a voltage VS2. The voltage VS2 is a voltage that turns the select transistor ST1 on when the voltage VSS is applied to the bit line BL thereof, and turns the select transistor ST1 off when the voltage VBL2 is applied to the bit line BL thereof. The voltage VS2 is, for example, equal to or lower than the voltage VS1. As a result, the channel of the NAND string NS corresponding to the bit line BL (“1”) is set to a floating state.

At a time t23, the sense amplifier module 17 applies a voltage VQPW to the bit line BL (“QPW”).

As described above, the voltage VSS is applied to the bit line BL corresponding to the first programming condition. Then, the voltage VQPW higher than the voltage VSS is applied to the bit line BL corresponding to the second programming condition. As described above, by changing the voltage of the bit line BL, in the same program operation, each bit line BL can be set to the program operation of “0” of the first programming condition, the program operation of “0” of the second programming condition, and the program operation of “1”.

At a time t24, the row decoder module 16 selects any word line WL in the selected block BLK, applies the voltage VPGM to the selected word line, and applies a voltage VPASS to the non-selected word lines WL.

In the NAND string NS corresponding to the bit line BL (“0”), the select transistor ST1 is turned on. Then, a channel voltage of the memory cell transistor MT connected to the selected word line WL is set to VSS. Therefore, the voltage difference between the control gate and the channel (VPGM-VSS) is increased, and as a result, electrons are injected into the charge storage layer and the threshold voltage of the memory cell transistor MT is raised.

In the NAND string NS corresponding to the bit line BL (“1”), the select transistor ST1 is set to a cut-off state. Accordingly, the channel of the memory cell transistor MT connected to the selected word line WL is electrically floating. Consequently, the channel voltage rises by capacitive coupling with the word line WL or the like. Accordingly, the voltage difference between the control gate and the channel is reduced, and as a result, electrons are hardly injected into the charge storage layer and the threshold voltage of the memory cell transistor MT is maintained (the threshold voltage does not change enough for the threshold voltage distribution level to transition to a higher distribution).

In the NAND string NS corresponding to the bit line BL (“QPW”), the select transistor ST1 is turned on. Then, a channel voltage of the memory cell transistor MT connected to the selected word line WL is set to VQPW (>VSS). Accordingly, the voltage difference between the control gate and the channel (VPGM-VQPW) is smaller than when the channel voltage is set to VSS. As a result, the amount of electrons injected into the charge storage layer is less than the memory cell transistor MT corresponding to the bit line BL (“0”), and the amount of increase in the threshold voltage of the memory cell transistor MT is also reduced.

At a time t25, the row decoder module 16 applies the voltage VSS to all of the word lines WL. As a result, charge injection into the charge storage layer is completed.

At a time t26, the row decoder module 16 applies the voltage VSS to the select gate line SGD. Application of a voltage VCELSRC to the source line SL is stopped, and the voltage VSS is applied to the source line SL. The sense amplifier module 17 applies the voltage VSS to the bit line BL.

Consequently, the program operation is completed.

### 1.2.5 Operation Example of Write Operation

The write operation using the semiconductor memory device 1 according to the embodiment will be described in more detail below.

The semiconductor memory device 1 according to the embodiment executes, for example, the write operation based on a first operation to be described below for one page of each block BLK. Then, for example, based on the write operation of the same one page, during subsequent write operations in the same block BLK, the semiconductor memory device 1 executes the write operation based on a second operation in which the first sensing operation is omitted in at least a part of the loop operations, as described below.

### 1.2.5.1 First Operation

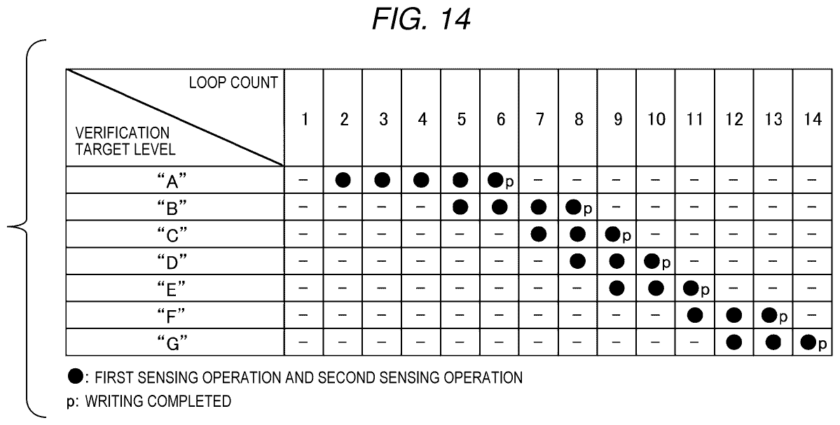

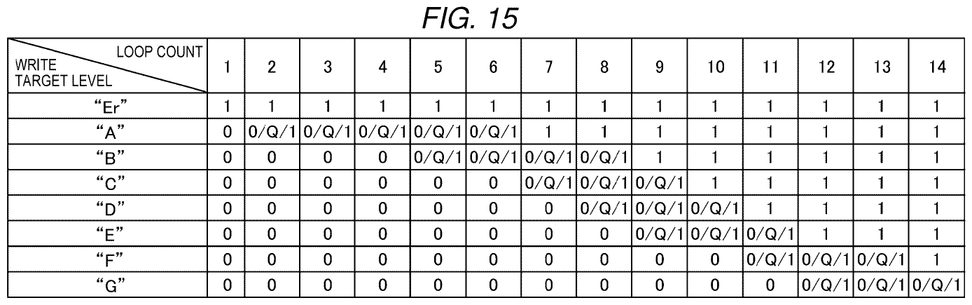

The first operation of the write operation will be described with reference to FIGS. 14 and 15. FIG. 14 is a diagram showing a relationship between the loop count and the verification operation during the write operation using the semiconductor memory device according to the embodiment. FIG. 15 is a diagram showing a relationship between the loop count and a bit line voltage during the write operation using the semiconductor memory device according to the embodiment.

Hereinafter, during the write operation, an example in which data is written by repeating the loop operation 14 times is described as an example. The number of loop operations executed during the write operation is referred to as the loop count.

FIG. 14 shows a target level of the verification operation performed in each loop operation. In the first loop operation, the verification operation is not executed as described above.

In second to fourth loop operations, the target level of the verification operation (verification target level) is only an “A” level. That is, during the verification operation, the voltage VfyA is applied to the selected word line WL, and the voltages VfyB to VfyG are not applied. In the verification operation of the first operation, the first sensing operation and the second sensing operation are executed for each verification target level. In FIG. 14, the execution of both the first sensing operation and the second sensing operation is indicated by filled circles.

In fifth and sixth loop operations, the verification target levels are the “A” level and a “B” level. That is, during the verification operation, the voltages VfyA and VfyB are sequentially applied to the selected word line WL, and the voltages VfyC to VfyG are not applied. The verification operation for the “A” level is completed by the sixth loop operation. That is, when the program operation of the sixth loop operation is executed, the threshold voltage of the memory cell transistor MT reaches the voltage VH (VfyA) (a state of verify pass for the “A” state and writing is completed). In FIG. 14, the loop operation in which writing to the verification target level is completed is indicated by “p”. The loop operation in which program of each level is completed may be statistically determined, for example, based on the first operation.

In a seventh loop operation, the verification target level is the “B” level and a “C” level. That is, during the verification operation, the voltages VfyB and VfyC are sequentially applied to the selected word line WL, and the voltages VfyA and VfyD to VfyG are not applied.

In an eighth loop operation, the verification target level is the “B” level, the “C” level, and a “D” level. That is, during the verification operation, the voltages VfyB, VfyC, and VfyD are sequentially applied to the selected word line WL, and the voltages VfyA and VfyE to VfyG are not applied. The verification operation for the “B” level is completed by the eighth loop operation. That is, when the program operation of the eighth loop operation is executed, the threshold voltage of the memory cell transistor MT reaches the voltage VH (VfyB).

In a ninth loop operation, the verification target level is the “C” level, the “D” level, and an “E” level. That is, during the verification operation, the voltages VfyC, VfyD, and VfyE are successively applied to the selected word line WL, and the voltages VfyA, VfyB, VfyF, and VfyG are not applied. The verification operation for the “C” level is completed by the ninth loop operation. That is, when the program operation of the ninth loop operation is executed, the threshold voltage of the memory cell transistor MT reaches the voltage VH (VfyC).

In a tenth loop operation, the verification target level is the “D” level and the “E” level. That is, during the verification operation, the voltages VfyD and VfyE are sequentially applied to the selected word line WL, and the voltages VfyA to VfyC, VfyF, and VfyG are not applied. The verification operation for the “D” level is completed by the tenth loop operation. That is, when the program operation of the tenth loop operation is executed, the threshold voltage of the memory cell transistor MT reaches the voltage VH (VfyD).

In an eleventh loop operation, the verification target level is the “E” level and an “F” level. That is, during the verification operation, the voltages VfyE and VfyF are sequentially applied to the selected word line WL, and the voltages VfyA to VfyD and VfyG are not applied. The verification operation for the “E” level is completed by the eleventh loop operation. That is, when the program operation of the eleventh loop operation is executed, the threshold voltage of the memory cell transistor MT reaches the voltage VH (VfyE).

In twelfth and thirteenth loop operations, the verification target levels are the “F” level and a “G” level. That is, during the verification operation, the voltages VfyF and VfyG are sequentially applied to the selected word line WL, and the voltage VfyA to VfyE are not applied. The verification operation for the “F” level is completed by the thirteenth loop operation. That is, when the program operation of the thirteenth loop operation is executed, the threshold voltage of the memory cell transistor MT reaches the voltage VH (VfyF).

In a fourteenth loop operation, the verification target level is the “G” level. That is, during the verification operation, the voltage VfyG is applied to the selected word line WL, and the voltage VfyA to VfyF are not applied. The verification operation for the “G” level is completed by the fourteenth loop operation. That is, when the program operation of the fourteenth loop operation is executed, the threshold voltage of the memory cell transistor MT reaches the voltage VH (VfyG).

FIG. 15 corresponds to FIG. 14 and shows a state of the bit line BL according to the target level of writing in the program operation performed in each loop. In FIG. 15, the notation “1” indicates that the program operation of “1” is executed. The notation “0” indicates that the program operation of “O” applying the first programming condition is executed. The notation “Q” indicates that the program operation of “0” applying the second programming condition is executed.

When the threshold voltage of the memory cell transistor MT is to be maintained at the “Er” level, the program operation of “1” is executed in all of the loops.

When the write target level is the “A” level, the program operation of “0” is performed in the first to sixth loop operations. The operations correspond to the first loop operation and a loop operation in which the verification operation for the “A” level is performed. Until verify pass is determined, the program operation of “0” applying the first programming condition or the second programming condition is executed depending on the result of the immediately previous verification operation. When verify pass is determined, the program operation of “1” is executed. In FIG. 15, the program operation of “0” is executed in the first loop operation during which the program operation is not executed, and in the second to sixth loop operations, the program operation of “0” applying the first programming condition or the second programming condition or the program operation of “1” is executed depending on whether verify pass is determined. After writing to the “A” level is completed, in the seventh and subsequent loop operations, the program operation of “1” is executed and writing is inhibited.

When the write target level is the “B” level, the program operation of “0” is performed in the first to eighth loop operations. The operations correspond to the first loop operation and a loop operation in which the verification operation for at least one of the “A” level and the “B” level is performed. For example, in loop operations before the loop operation in which the “B” level is the verification target level, the program operation of “0” is executed. That is, in the first to fourth loop operations, the program operation of “0” is executed. In the loop operation in which the “B” level is the verification target level, the program operation of “0” applying the first programming condition or the second programming condition is executed depending on the result of the immediately previous verification operation until verify pass is determined. When verify pass is determined, the program operation of “1” is executed. That is, in the fifth to eighth loop operations, the program operation of “0” applying the first programming condition or the second programming condition or the program operation of “1” is executed depending on whether verify pass is determined in the immediately previous verification operation. After writing to the “B” level is completed, in the ninth and subsequent loops, the program operation of “1” is executed and writing is inhibited.

When the write target level is the “C” level, the program operation of “0” is performed in the first to ninth loop operations. The operations correspond to the first loop operation and a loop operation in which the verification operation for at least one of the “A” level, the “B” level, and the “C” level is performed. For example, in loop operations before the loop operation in which the “C” level is the verification target level, the program operation of “0” is executed. That is, in the first to sixth loop operations, the program operation of “0” is executed. In the loop operation in which the “C” level is the verification target level, the program operation of “0” applying the first programming condition or the second programming condition is executed depending on the result of the immediately previous verification operation until verify pass is determined. When verify pass is determined, the program operation of “1” is executed. That is, in the seventh to ninth loop operations, the program operation of “0” applying the first programming condition or the second programming condition or the program operation of “1” is executed depending on whether verify pass is determined in the immediately previous verification operation. After writing to the “C” level is completed, in the tenth and subsequent loops, the program operation of “1” is executed and writing is inhibited.

When the write target level is the “D” level, the program operation of “0” is performed in the first to tenth loop operations. The operations correspond to the first loop operation and a loop operation in which the verification operation for at least one of the “A” level, the “B” level, the “C” level, and the “D” level is performed. For example, in loop operations before the loop operation in which the “D” level is the verification target level, the program operation of “O” is executed. That is, in the first to seventh loop operations, the program operation of “0” is executed. In the loop operation in which the “D” level is the verification target level, the program operation of “0” applying the first programming condition or the second programming condition is executed depending on the result of the immediately previous verification operation until verify pass is determined. When verify pass is determined, the program operation of “1” is executed. That is, in the eighth to tenth loop operations, the program operation of “0” applying the first programming condition or the second programming condition or the program operation of “1” is executed depending on whether verify pass is determined in the immediately previous verification operation. After writing to the “D” level is completed, in the eleventh and subsequent loops, the program operation of “1” is executed and writing is inhibited.

When the write target level is the “E” level, the program operation of “0” is performed in the first to eleventh loop operations. The operations correspond to the first loop operation and a loop operation in which the verification operation for at least one of the “A” level, the “B” level, the “C” level, the “D” level, and the “E” level is performed. For example, in loop operations before the loop operation in which the “E” level is the verification target level, the program operation of “0” is executed. That is, in the first to eighth loop operations, the program operation of “0” is executed. In the loop operation in which the “E” level is the verification target level, the program operation of “0” applying the first programming condition or the second programming condition is executed depending on the result of the immediately previous verification operation until verify pass is determined. When verify pass is determined, the program operation of “1” is executed. That is, in the ninth to eleventh loop operations, the program operation of “0” applying the first programming condition or the second programming condition or the program operation of “1” is executed depending on whether verify pass is determined in the immediately previous verification operation. After writing to the “E” level is completed, in the twelfth and subsequent loops, the program operation of “1” is executed and writing is inhibited.

When the write target level is the “F” level, the program operation of “0” is performed in the first to thirteenth loop operations. The operations correspond to the first loop operation and a loop operation in which the verification operation for at least one of the “A” level, the “B” level, the “C” level, the “D” level, the “E” level, and the “F” level is performed. For example, in the loop operation before the loop operation in which the “F” level is the verification target level, the program operation of “0” is executed. That is, in the first to tenth loop operations, the program operation of “0” is executed. In the loop operation in which the “F” level is the verification target level, the program operation of “0” applying the first programming condition or the second programming condition is executed depending on the result of the immediately previous verification operation until verify pass is determined. When verify pass is determined, the program operation of “1” is executed. That is, in the eleventh to thirteenth loop operations, the program operation of “0” applying the first programming condition or the second programming condition or the program operation of “1” is executed depending on whether verify pass is determined in the immediately previous verification operation. After writing to the “F” level is completed, in the fourteenth loop operation, the program operation of “1” is executed and writing is inhibited.

When the write target level is the “G” level, the program operation of “0” is performed in the first to fourteenth loop operations. The operations correspond to the first loop operation and a loop operation in which the verification operation for at least one of the “A” level, the “B” level, the “C” level, the “D” level, the “E” level, the “F” level, and the “G” level is performed. For example, in the loop operation before the loop operation in which the “G” level is the verification target level, the program operation of “0” is executed. That is, in the first to eleventh loop operations, the program operation of “0” is executed. In the loop operation in which the “G” level is the verification target level, the program operation of “0” applying the first programming condition or the second programming condition is executed depending on the result of the immediately previous verification operation until verify pass is determined. When verify pass is determined, the program operation of “1” is executed. That is, in the twelfth to fourteenth loop operations, the program operation of “0” applying the first programming condition or the second programming condition or the program operation of “1” is executed depending on whether verify pass is determined in the immediately previous verification operation. In the fourteenth loop operation, writing to the “G” level is completed.

### 1.2.5.2 Second Operation

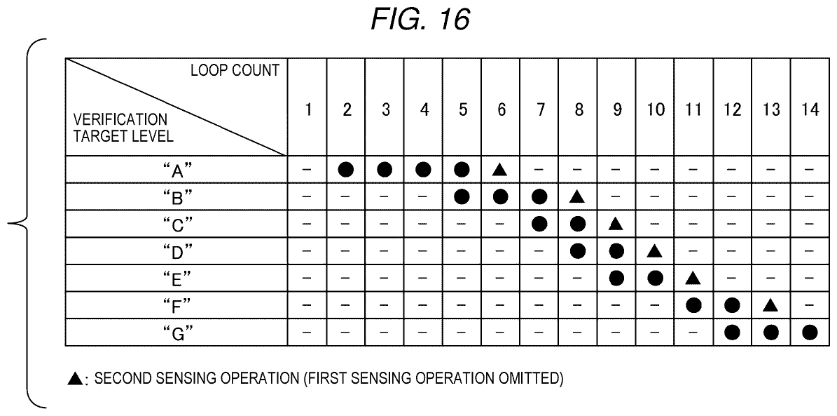

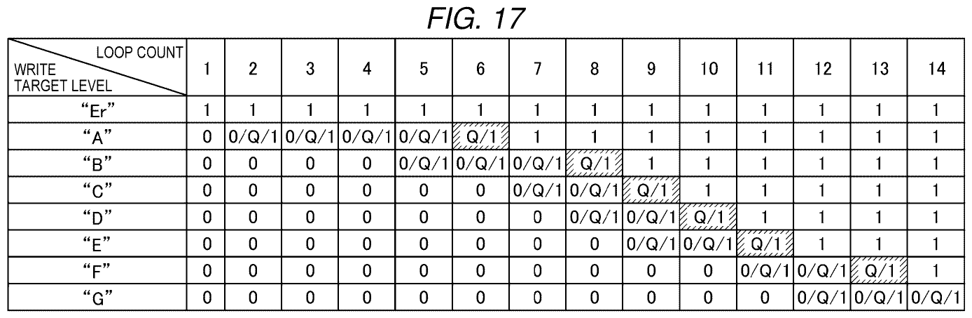

The second operation of the write operation will be described with reference to FIGS. 16 and 17. FIG. 16 is a diagram showing a relationship between the loop count and the verification operation during the write operation using the semiconductor memory device according to the embodiment. FIG. 17 is a diagram showing a relationship between the loop count and the bit line voltage during the write operation using the semiconductor memory device according to the embodiment. In the following description, the second operation will be described mainly with respect to differences from the first operation. For example, a target page of the write operation of the second operation is in the same block BLK as the target page of the write operation of the first operation.

In the first operation described above, it is expected that the loop operation in which writing to each level is completed will be the same even in the write operations different from the first operation. In the semiconductor memory device 1, for example, regarding write characteristics for the loop operation in which writing to each level is completed (completion loop operation), write characteristics of a page for which the first operation is executed are assumed to be the same as write characteristics of a different page. As a result, in the semiconductor memory device 1, for the same level, a completion loop operation number of the different page is assumed to be the same as a completion loop operation number of the page for which the first operation is executed. In the second operation, the semiconductor memory device 1 considers the loop operation in which programming for each level is completed to be the loop operation in which writing is expected to be completed. Then, in the loop operation in which writing to each of the “A” state to the “F” state is expected to be completed, the semiconductor memory device 1 omits the first sensing operation for the verification target level and executes only the second sensing operation. FIG. 16 shows, regarding the verification target level of the loop operation in which writing is expected to be completed, omission of the first sensing operation and execution of the second sensing operation by partial hashing. In the following description, the loop operation in which writing to the verification target level is expected to be completed is simply referred to as a pass loop operation.

In the following description, an example will be shown in which both the first sensing operation and the second sensing operation are executed in the loop operation in which writing to the “G” state is expected to be completed, but the embodiments are not limited thereto. Even in the expected loop operation, the first sensing operation may be omitted and the second sensing operation may be executed.

In the sixth loop operation of the second operation, the first sensing operation is omitted and the second sensing operation is executed for the “A” level. In the eighth loop operation, the first sensing operation is omitted and the second sensing operation is executed for the “B” level. In the ninth loop operation, the first sensing operation is omitted and the second sensing operation is executed for the “C” level. In the tenth loop operation, the first sensing operation is omitted and the second sensing operation is executed for the “D” level. In the eleventh loop operation, the first sensing operation is omitted and the second sensing operation is executed for the “E” level. In the thirteenth loop operation, the first sensing operation is omitted and the second sensing operation is executed for the “F” level.

FIG. 17 corresponds to FIG. 16 and shows a state of the bit line BL according to the target level of writing in the program operation performed in each loop.

When the write target level is the “A” level, in the sixth loop operation in which the first sensing operation for the “A” level is omitted, when the second sensing operation for the “A” level is determined as verify fail, the program operation of “0” applying the second programming condition is executed. In the sixth loop operation, when the second sensing operation for the “A” level is determined as verify pass, the program operation of “1” is executed and writing is inhibited.

When the write target level is the “B” level, in the eighth loop operation in which the first sensing operation for the “B” level is omitted, when the second sensing operation for the “B” level is determined as verify fail, the program operation of “0” applying the second programming condition is executed. In the eighth loop operation, when the second sensing operation for the “B” level is determined as verify pass, the program operation of “1” is executed and writing is inhibited.

When the write target level is the “C” level, in the ninth loop operation in which the first sensing operation for the “C” level is omitted, when the second sensing operation for the “C” level is determined as verify fail, the program operation of “0” applying the second programming condition is executed. In the ninth loop operation, when the second sensing operation for the “C” level is determined as verify pass, the program operation of “1” is executed and writing is inhibited.

When the write target level is the “D” level, in the tenth loop operation in which the first sensing operation for the “D” level is omitted, when the second sensing operation for the “D” level is determined as verify fail, the program operation of “0” applying the second programming condition is executed. In the tenth loop operation, when the second sensing operation for the “D” level is determined as verify pass, the program operation of “1” is executed and writing is inhibited.

When the write target level is the “E” level, in the eleventh loop operation in which the first sensing operation for the “E” level is omitted, when the second sensing operation for the “E” level is determined as verify fail, the program operation of “0” applying the second programming condition is executed. In the eleventh loop operation, when the second sensing operation for the “E” level is determined as verify pass, the program operation of “1” is executed and writing is inhibited.

When the write target level is the “F” level, in the thirteenth loop operation in which the first sensing operation for the “F” level is omitted, when the second sensing operation for the “F” level is determined as verify fail, the program operation of “0” applying the second programming condition is executed. In the thirteenth loop operation, when the second sensing operation for the “F” level is determined as verify pass, the program operation of “1” is executed and writing is inhibited.

As described above, for example, after the first operation, the semiconductor memory device 1 executes the write operation based on the second operation in the block BLK in which the first operation is executed. As a result, writing of “A” to “G” levels is performed.

Even in the loop operation in which writing to the “G” state is expected to be completed, when the first sensing operation is omitted and the second sensing operation is executed, in the fourteenth loop operation, when the second sensing operation for the “G” level is determined as verify fail, the program operation of “0” applying the second programming condition is executed. In the fourteenth loop operation, when the second sensing operation for the “G” level is determined as verify pass, the program operation of “1” is executed and writing is inhibited.

### 1.3 Effects

According to the embodiment, a processing speed can be improved. Effects of the embodiment will be described below.

The semiconductor memory device 1 according to the embodiment repeatedly executes the loop operation of sequentially executing the verification operation of confirming the threshold voltage and the program operation of raising the threshold voltage during the write operation of writing the plurality of memory cell transistors MT to a first state. In the verification operation of the loop operation immediately before the loop operation in which writing of the plurality of memory cell transistors MT to the first state is completed, the semiconductor memory device 1 executes the first sensing operation and the second sensing operation for the first state. In the verification operation of the loop operation in which writing to the first state is completed, the semiconductor memory device 1 omits the first sensing operation and executes only the second sensing operation. With such a configuration, the processing speed is improved compared to when both the first sensing operation and the second sensing operation are executed in the loop operation in which writing to the first state is completed.

In the semiconductor memory device 1 according to the embodiment, in the loop operation in which writing to the first state is completed, the program operation of “0” applying the second programming condition is executed for the memory cell transistor MT of which the threshold voltage is determined to be lower than the voltage VH by the second sensing operation. For the memory cell transistor MT of which the threshold voltage is determined to be equal to or higher than the voltage VH by the second sensing operation, the program operation of “1” is executed and writing is inhibited. With such a configuration, excessive writing (Over Program) and insufficient writing can be prevented while improving a processing speed.

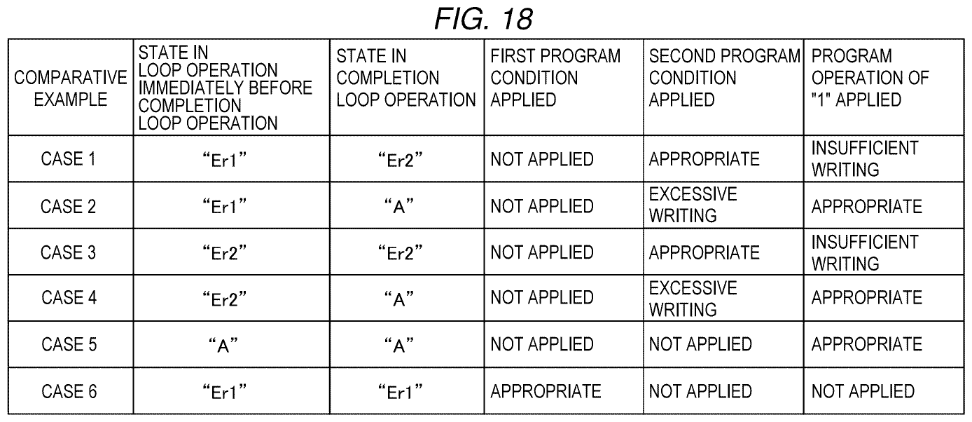

The effects of the embodiment are further described using a comparative example. In the comparative example, to improve a processing speed, only the first sensing operation is executed in the completion loop operation for writing to the first state and the second sensing operation is not executed. For simplicity, writing from the “Er” state to the “A” state is assumed. The write operation of the comparative example will be described with reference to FIG. 18. FIG. 18 is a diagram showing the write operation in the semiconductor memory device according to the comparative example.

The memory cell transistor MT determined to be in the “Er1” state by the verification operation in the loop operation immediately before the completion loop operation may be written to the “Er2” state by the program operation of the loop operation immediately before the completion loop operation, for example, as illustrated in Case 1 of FIG. 18. The semiconductor memory device of the comparative example cannot determine between the “Er2” state and the “A” state in the verification operation of the completion loop operation. As a result, when the second programming condition is applied in the completion loop operation (when processing is executed assuming the “Er2” state), excessive writing and insufficient writing does not occur (writing is appropriate). However, in the completion loop operation, when the program operation of “1” is executed (when processing is executed assuming the “A” state), insufficient writing occurs. Note that, in the first sensing operation of the completion loop operation, the first programming condition is not applied.

The memory cell transistor MT determined to be in the “Er1” state by the verification operation in the loop operation immediately before the completion loop operation may be written to the “A” state by the program operation of the loop operation immediately before the completion loop operation, for example, as illustrated in Case 2 of FIG. 18. Even then, the semiconductor memory device of the comparative example cannot determine between the “Er2” state and the “A” state in the verification operation of the completion loop operation. As a result, when the second programming condition is applied in the completion loop operation (when processing is executed assuming the “Er2” state), excessive writing may occur. In the completion loop operation, when the program operation of “1” is executed (when processing is executed assuming the “A” state), no problem occurs. Note that, in the first sensing operation of the completion loop operation, the first programming condition is not applied.

The memory cell transistor MT determined to be in the “Er2” state by the verification operation in the loop operation immediately before the completion loop operation may be maintained at the “Er2” state by the program operation of the loop operation immediately before the completion loop operation, for example, as illustrated in Case 3 of FIG. 18. Even then, in the comparative example, as illustrated in Case 1 of FIG. 18, when the program operation of “1” is executed in the completion loop operation, insufficient writing may occur.

The memory cell transistor MT determined to be in the “Er2” state by the verification operation in the loop operation immediately before the completion loop operation may be written to the “A” state by the program operation of the loop operation immediately before the completion loop operation, for example, as illustrated in Case 4 of FIG. 18. Even then, as illustrated in Case 2 of FIG. 18, when the second programming condition is applied in the completion loop operation, excessive writing may occur.

When the “A” state is determined by the verification operation in the loop operation immediately before the completion loop operation, as illustrated in Case 5 of FIG. 18, no problem occurs because the program operation of “1” is applied in the completion loop operation.

As illustrated in Case 6 of FIG. 18, a memory cell transistor of which the threshold voltage is lower than the voltage VL (in the “Er1” state) even when the completion loop operation is executed may be assumed. Here, in the completion loop operation, the first programming condition is applied, and neither the second programming condition is applied nor the program operation of “1” is executed.

According to the embodiment, the semiconductor memory device 1 executes only the second sensing operation without executing the first sensing operation in the loop operation in which writing to the first state is completed. With such a configuration, excessive writing can be prevented. That is, whether the first state is reached by the loop operation immediately before the completion loop operation can be determined in the second sensing operation. As a result, the semiconductor memory device 1 can appropriately execute the program operation of “0” applying the second programming condition or the program operation of “1”.

When the completion loop operation is executed, it is assumed that, due to the progress of writing, the number of memory cell transistors MT of which the threshold voltage is lower than the voltage VL is small, as illustrated in Case 6 of FIG. 18. Therefore, a need to determine between the “Er1” state and the “Er2” state by the first sensing operation in the completion loop operation is considered to be low. Therefore, by omitting the first sensing operation in the completion loop operation, the program operation of “0” applying the second programming condition is applied to the memory cell transistor MT of which the threshold voltage is lower than the voltage VL, such that insufficient writing can be prevented.

The memory cell transistor corresponding to Case 6 of FIG. 18 may be a memory cell transistor having non-standard characteristics. That is, compared to the memory cell transistor having standard characteristics, the threshold voltage rises more slowly, and even when the program voltage is applied for a standard loop count, the memory cell transistor is likely to be determined as verify fail and result in an error. In the embodiment, the error in such a writing operation of the memory cell transistor may be corrected, for example, by the ECC circuit 25 of the memory controller 2. Therefore, according to the embodiment, it is possible to focus on errors that are difficult to avoid by the write operation itself, allow occurrence of such errors, and omit the process of raising the threshold voltage of the memory cell transistors that would result in such errors. Accordingly, it is possible to shorten a processing time without substantially deteriorating accuracy of the write operation of the semiconductor memory device 1.

### 2. MODIFICATIONS OF EMBODIMENT

The embodiment described above may be modified in various ways. Hereinafter, semiconductor memory devices according to modifications of the embodiment will be described.

### 2.1 First Modification

In the embodiment described above, an example is illustrated in which, in each of the loop operations where writing for the “A” state to the “F” state is expected to be completed, the first sensing operation is omitted and only the second sensing operation is executed, but the embodiments are not limited thereto. In each of the loop operations, both the first sensing operation and the second sensing operation may be omitted depending on the result of the verification operation of the loop operation before the current loop operation.

### 2.1.1 Configuration

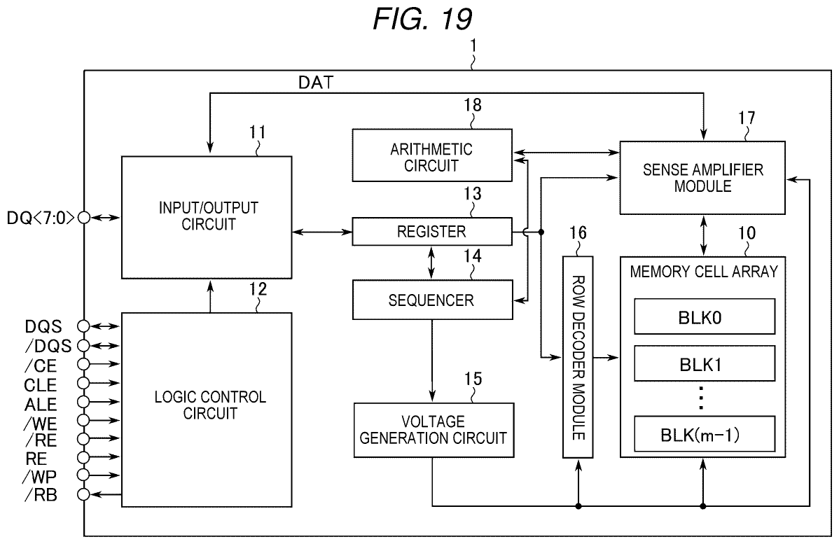

A configuration of the semiconductor memory device 1 according to a first modification will be described with reference to FIG. 19. FIG. 19 is a block diagram showing an example of the configuration of the semiconductor memory device according to the first modification.

The semiconductor memory device 1 further includes an arithmetic circuit 18.

The arithmetic circuit 18 performs various arithmetic operations, for example, using data stored in the sense amplifier module 17 based on an instruction from the sequencer 14. The various operations may be executed by the sequencer 14. Here, the semiconductor memory device 1 may not include the arithmetic circuit 18. The arithmetic circuit 18 may be a component of the sense amplifier module 17. For example, the arithmetic circuit 18 may execute calculations in parallel with the program operation or the verification operation, using the result of the verification operation executed before to the current operations.

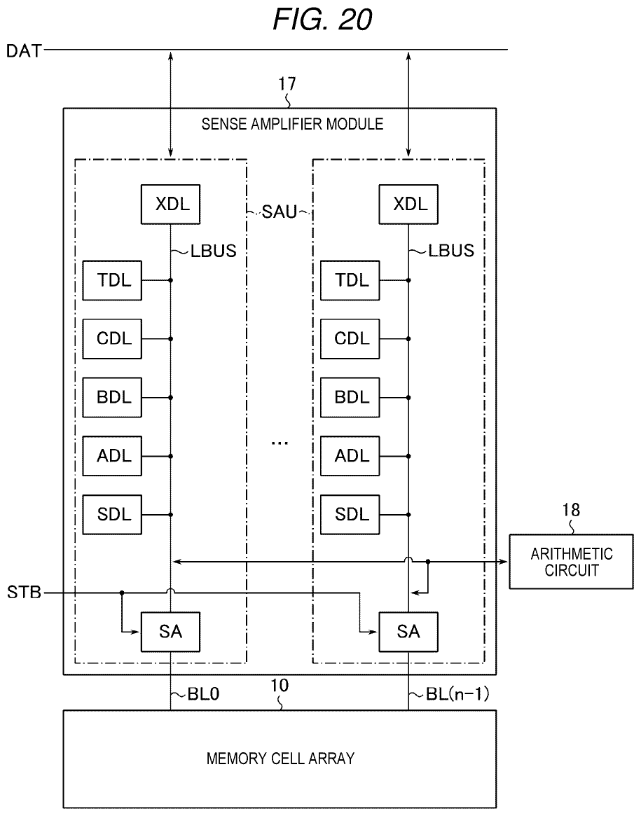

A configuration of the sense amplifier module 17 of the semiconductor memory device 1 according to the first modification will be described with reference to FIG. 20. FIG. 20 is a block diagram showing an example of the configuration of the sense amplifier module of the semiconductor memory device according to the first modification.

The bus LBUS of each sense amplifier unit SAU is connected to, for example, the arithmetic circuit 18. As a result, the arithmetic circuit 18 is configured to be able to perform arithmetic operations using, for example, data stored in the latch circuits SDL, ADL, BDL, CDL, and TDL in each sense amplifier unit SAU.

### 2.1.2 Write Operation of First Modification

An example of a write operation of the first modification will be described.

The semiconductor memory device 1 according to the first modification executes the first operation, for example, similarly to the embodiment. Meanwhile, the semiconductor memory device 1 according to the first modification executes a third operation instead of the second operation. In the third operation, for example, in the loop operation in which writing is expected to be completed, the semiconductor memory device 1 omits both the first sensing operation and the second sensing operation depending on the result of the verification operation of the loop operation before the current loop operation. In the third operation, the semiconductor memory device 1 according to the first modification executes loop operations other than the loop operation in which writing is expected to be completed, similarly to the second operation of the embodiment.

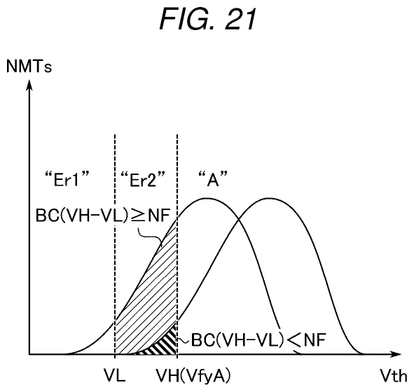

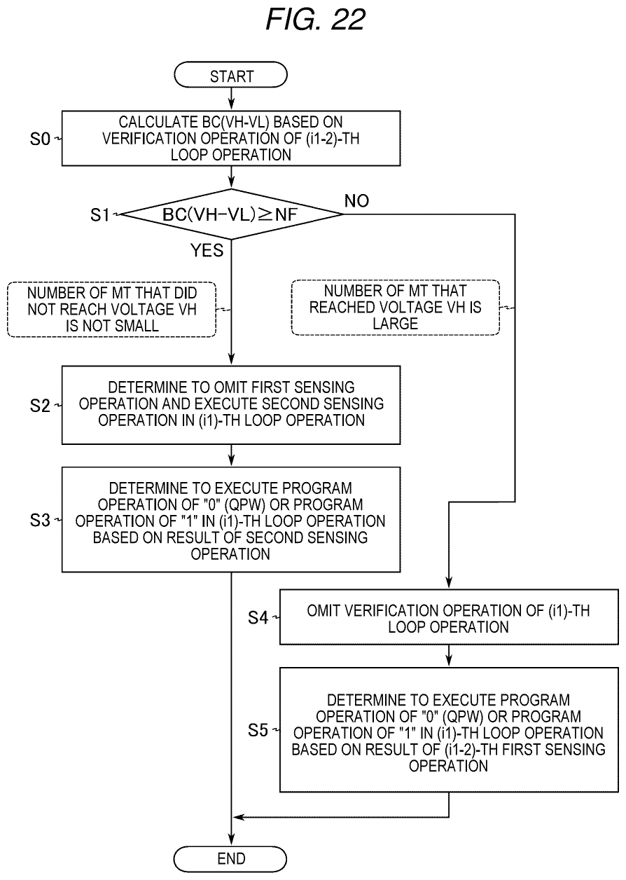

The third operation of the first modification will be described with reference to FIGS. 21 and 22. FIG. 21 is a diagram showing selection of an operation during the write operation using the semiconductor memory device according to the first modification. FIG. 22 is a flowchart showing the selection of the operation during the write operation using the semiconductor memory device according to the first modification.

FIG. 21 shows an example of a threshold voltage distribution in two different stages while the memory cell transistor MT is being written from the “Er” state to the “A” state.

The arithmetic circuit 18 calculates the number of memory cell transistors MT of which the threshold voltages are between the voltages VH and VL (equal to or higher than the voltage VL and lower than the voltage VH) based on the result of the verification operation. Hereinafter, the number of such memory cell transistors MT is referred to as a bit count BC(VH−VL) (a hatched area in FIG. 21). The bit count BC(VH−VL) may be used to determine a degree of completion of writing.

The arithmetic circuit 18 calculates the bit count BC(VH−VL) for a verification target level using the result of the verification operation of the loop operation before the loop operation in which writing to the verification target level is expected to be completed. The arithmetic circuit 18 calculates the bit count BC(VH−VL) using, for example, the result of the verification operation of the loop operation before the loop operation in which writing is expected to be completed. When the verification target level is the “A” level and the loop operation in which writing is expected to be completed is the sixth loop operation, for example, the arithmetic circuit 18 calculates the bit count BC(VH−VL) using the result of the verification operation of the fourth loop operation.

The arithmetic circuit 18 determines whether the calculated bit count BC(VH−VL) is equal to or greater than a reference value NF. Meanwhile, when the bit count BC(VH−VL) is determined to be equal to or greater than the reference value NF (BC(VH−VL)≥NF), the semiconductor memory device 1 estimates that, immediately before the loop operation in which writing is expected to be completed (at a timing at which the loop operation immediately before the loop operation in which writing is expected to be completed is completed), the number of memory cell transistors MT that did not reach the voltage VH (that were determined as verify fail in the second sensing operation) is not small. When the bit count BC(VH−VL) is determined to be less than the reference value NF (BC(VH−VL)<NF), the semiconductor memory device 1 estimates that the number of memory cell transistors MT that reached voltage VH (that were determined as verify pass in the second sensing operation) is large immediately before the loop operation in which writing is expected to be completed.

Then, based on the result of the determination, the semiconductor memory device 1 determines the content of the loop operation in which writing is expected to be completed.

The determination of the content of the loop operation in which writing is expected to be completed will be described with reference to FIG. 22. In FIG. 22, a loop operation in which writing to each of the “A” state to the “F” state is expected to be completed is defined as an (i1)-th loop operation.

The arithmetic circuit 18 calculates the bit count BC(VH−VL) using the result of the verification operation of an (i1-2)-th loop operation for the verification target level (S0). For example, the arithmetic circuit 18 calculates the bit count BC(VH−VL) in parallel with the loop operation before the verification operation of the (i1)-th loop operation.

The arithmetic circuit 18 determines whether the calculated bit count BC(VH−VL) is equal to or greater than the reference value NF (S1). When the bit count BC(VH−VL) is determined to be equal to or greater than the reference value NF (S1; YES), the processing proceeds to S2. When the bit count BC(VH−VL) is determined to be less than the reference value NF (S1; NO), the processing proceeds to S14.

When the bit count BC(VH−VL) is determined to be equal to or greater than the reference value NF (S1; YES), the semiconductor memory device 1 determines to omit the first sensing operation of the verification target level and execute the second sensing operation in the verification operation of the (i1)-th loop operation (S2). That is, the verification operation similar to the second operation of the embodiment is executed. Then, the process proceeds to S3.

In the (i1)-th loop operation, the semiconductor memory device 1 determines to execute the program operation of “0” applying the second programming condition or the program operation of “1” based on the result of the verification operation of the (i1)-th loop operation (S3). That is, similarly to the second operation of the embodiment, in the (i1)-th loop operation, the semiconductor memory device 1 executes the program operation of “0” applying the second programming condition for the memory cell transistor MT determined as verify fail in the second sensing operation. Meanwhile, the semiconductor memory device 1 executes the program operation of “1” and inhibits writing for the memory cell transistor MT determined as verify pass in the second sensing operation. Then, determination of the content of the (i1)-th loop operation is completed.

When the bit count BC(VH−VL) is determined to be less than the reference value NF (S1; NO), the semiconductor memory device 1 determines to omit both the first sensing operation and the second sensing operation for the verification target level in the verification operation of the (i1)-th loop operation (S4). Then, the process proceeds to S5.

The semiconductor memory device 1 determines to execute the program operation of “0” applying the second programming condition or the program operation of “1” in the (i1)-th loop operation based on the result of the first sensing operation of the (i1-2)-th loop operation (S5). More specifically, in the (i1-2)-th loop operation, the semiconductor memory device 1 executes the program operation of “0” applying the second programming condition for the memory cell transistor MT determined as verify fail in the first sensing operation. Meanwhile, the semiconductor memory device 1 executes the program operation of “1” and inhibits writing for the memory cell transistor MT determined as verify pass in the first sensing operation. Then, determination of the content of the (i1)-th loop operation is completed.

When the bit count BC(VH−VL) is determined to be less than the reference value NF, the semiconductor memory device 1 estimates that the number of memory cell transistors MT that reached the voltage VH is large immediately before the (i1)-th loop operation. That is, the semiconductor memory device 1 estimates that writing to the target level is close to completion as by progressing the writing. Consequently, in the (i1-2)-th loop operation, the semiconductor memory device 1 executes an operation of raising the threshold voltage only to the memory cell transistors MT of which the threshold voltage is lower than the voltage VL.

In the verification operation of the loop operation in which writing to the “G” state is expected to be completed, for example, as in the second operation of the embodiment, a loop operation similar to the first operation of the embodiment is executed, but the embodiments are not limited thereto. For the loop operation in which writing to the “G” state is expected to be completed, the content of the loop operation may be determined similarly to the writing for the “A” state to the “F” state.

According to the first modification, a processing speed can be improved similarly to the embodiment.

Excessive writing and insufficient writing can be prevented by the first modification. The effects are further described below.

According to the first modification, the semiconductor memory device 1 calculates the bit count BC(VH−VL) based on the first sensing operation and the second sensing operation executed before the loop operation in which writing to the first state is completed. The semiconductor memory device 1 determines whether the bit count BC(VH−VL) is equal to or greater than the reference value NF. When the bit count BC(VH−VL) is equal to or greater than the reference value NF, the semiconductor memory device 1 omits the first sensing operation and executes only the second sensing operation in the loop operation in which writing to the first state is completed. Then, the semiconductor memory device 1 executes the program operation of “0” applying the second programming condition for the memory cell transistor MT of which the threshold voltage is determined to be lower than the voltage VH by the second sensing operation. Meanwhile, the semiconductor memory device 1 executes the program operation of “1” for the memory cell transistor MT of which the threshold voltage is determined to be equal to or higher than the voltage VH by the second sensing operation. With the operation described above, excessive writing and insufficient writing can be prevented as in the embodiment.

When the bit count BC(VH−VL) is less than the reference value NF, the semiconductor memory device 1 does not execute any of the first sensing operation and the second sensing operation in the loop operation in which writing to the first state is completed. The semiconductor memory device 1 executes the program operation of “O” applying the second programming condition for the memory cell transistor MT of which the threshold voltage is determined to be lower than the voltage VL by the first sensing operation executed before the loop operation in which writing to the first state is completed. Meanwhile, the semiconductor memory device 1 executes the program operation of “1” for the memory cell transistor MT of which the threshold voltage is determined to be equal to or higher than the voltage VL by the first sensing operation executed before the loop operation in which writing to the first state is completed.

When the bit count BC(VH−VL) is less than the reference value NF, the number of memory cell transistors MT of which the threshold voltages are between the voltages VH and VL is assumed to be small, and the number of memory cell transistors MT of which the threshold voltages are equal to or higher than the voltage VH is assumed to be large. Here, writing to the first state of the memory cell transistor MT is assumed to be almost completed before the loop operation in which writing to the first state is completed is executed. More specifically, in the first sensing operation of the (i1-2)-th loop operation, writing of the memory cell transistor MT of which the threshold voltage is equal to or higher than the voltage VL is assumed to be completed before the (i1)-th loop operation. Meanwhile, in the first sensing operation of the (i1-2)-th loop operation, writing of the memory cell transistor MT of which the threshold voltage is lower than the voltage VL is assumed to not be completed before the (i1)-th loop operation. The threshold voltages of such memory cell transistors MT immediately before the (i1)-th loop operation are assumed to be interposed between, for example, the voltage VH and the voltage VL. Therefore, excessive writing can be prevented by executing the program operation of “1” for the memory cell transistor MT determined to have the threshold voltage equal to or higher than the voltage VL in the first sensing operation of the (i1-2)-th loop operation. In the first sensing operation, insufficient writing can be prevented by executing the program operation of “0” applying the second programming condition for the memory cell transistor MT determined to have the threshold voltage lower than the voltage VL.

### 2.2 Second Modification

In the embodiments described above, an example is illustrated in which each page has almost equivalent write characteristics, but the embodiments are not limited thereto. The semiconductor memory device may execute the write operation, for example, according to the write characteristics of each page.

### 2.2.1 Configuration

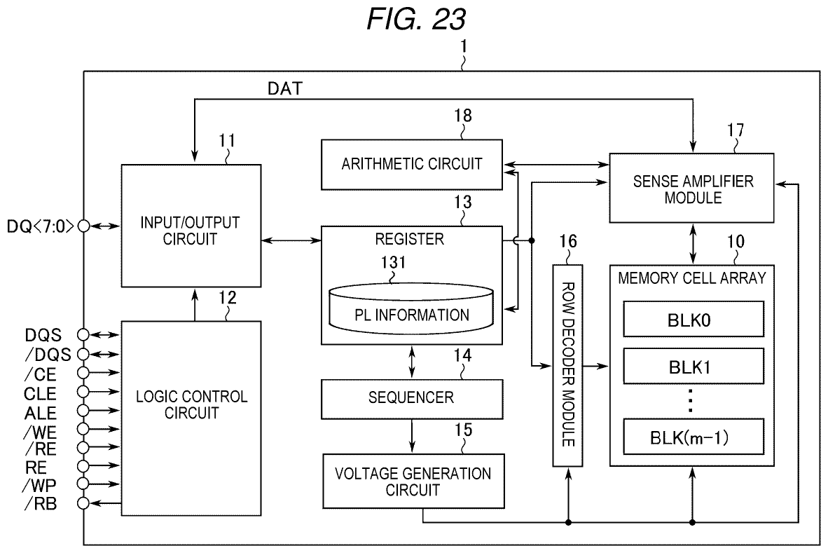

A configuration of the semiconductor memory device 1 according to a second modification will be described with reference to FIG. 23. FIG. 23 is a block diagram showing an example of the configuration of the semiconductor memory device according to the second modification.

The register 13 is provided with PL information 131. The PL information 131 stores, for example, write characteristics. The write characteristic includes, for example, a loop operation number in which writing to each verification target level is expected to be completed. The write characteristics may be acquired, for example, based on write operations already executed for pages. Here, for example, the semiconductor memory device 1 executes the write operation of the page similarly to the first operation of the embodiment. For example, the semiconductor memory device 1 determines the loop operation number in which writing to each target level is completed based on the bit count BC(VH−VL). The PL information 131 stores the determined number as the loop operation number in which writing to the verification target level is expected to be completed.

### 2.2.2 Operation

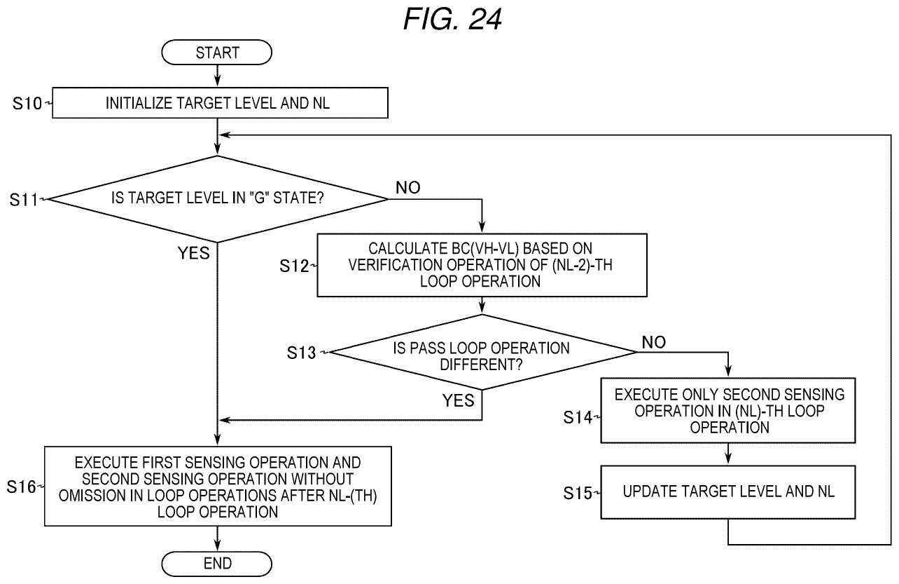

The write operation will be described with reference to FIG. 24. FIG. 24 is a flowchart showing selection of an operation during the write operation using the semiconductor memory device according to the second modification.

The semiconductor memory device 1 initializes a target level and a reference value NL (S10). That is, the verification target level is set to the “A” state. The reference value NL is set to a value corresponding to the “A” state. The reference value NL is a loop operation number in which writing to the set target level is expected to be completed. The reference value NL is based on the PL information 131.

In the loop operations before an (NL)-th loop, the semiconductor memory device 1 executes the loop operation similarly to the first operation of the embodiment.

The semiconductor memory device 1 determines whether the verification target level is the “G” state (S11). When the verification target level is the “G” state (S11; YES), the process proceeds to S16. When the verification target level is one of the “A” state to the “F” state (S11; NO), the process proceeds to S12.

The semiconductor memory device 1 calculates the bit count BC(VH−VL) based on the verification operation of an (NL-2)-th loop operation (S12).

The semiconductor memory device 1 determines whether the loop operation number in which writing to the writing target page is completed is different from the reference value NL (that is, whether the pass loop operation is different) based on the bit count BC(VH−VL) calculated in S12 (S13). For example, when the bit count BC(VH−VL) is less than a preset reference count number, the semiconductor memory device 1 determines that the pass loop operation is the same. When the bit count BC(VH−VL) is equal to or greater than the reference count, the semiconductor memory device 1 determines that the pass loop operation is different. The reference count may be set for each target level. When the pass loop operation is determined to be different (S13; YES), the process proceeds to S16. When the pass loop operation is determined to be the same (S13; NO), the process proceeds to S14.

When the pass loop operation is determined to be the same (S13; NO), as in the second operation of the embodiment, the semiconductor memory device 1 does not execute the first sensing operation and executes only the second sensing operation in the (NL)-th loop operation in which writing is expected to be completed (S14). The program operation of the loop operation is executed similarly to the second operation of the embodiment. In the processing of S14, the semiconductor memory device 1 may execute an operation similar to the third operation of the first modification instead of an operation similar to the second operation of the embodiment. Then, the process proceeds to S15.

The semiconductor memory device 1 updates the verification target level to the next level and updates the reference value NL to the reference value of the updated level (S15). Then, processing of S11 is executed again.

When the verification target level is the “G” state (S11; YES) and the pass loop operation is determined to be different (S13; YES), the semiconductor memory device 1 executes the loop operation after the (NL)-th loop, for example, similarly to the first operation of the first embodiment. That is, the semiconductor memory device 1 executes the first sensing operation and the second sensing operation without omission in (NL)-th and subsequent loop operations.

As described above, the semiconductor memory device 1 executes the loop operation similarly to the embodiment or the third operation of the first modification while the pass loop operation is determined to be the same (that is, the write characteristic of the target page is the same as the write characteristic stored in the PL information 131). When the pass loop operation is determined to be different (that is, the write characteristic of the target page is different from the write characteristic stored in the PL information 131), in the subsequent loop operations, the semiconductor memory device 1 executes the verification operation without omission similarly to the first operation of the embodiment.

The second modification also provides the effects equivalent to those of the embodiment.

### 2.3 Third Modification

In the second modification described above, an example is illustrated in which the semiconductor memory device executes the write operation according to the write characteristics of each page based on the write operation already executed for pages. However, the embodiments are not limited thereto. For example, the semiconductor memory device may execute the write operation based on the loop operation number in which writing to each verification target level set for each page is expected to be completed.

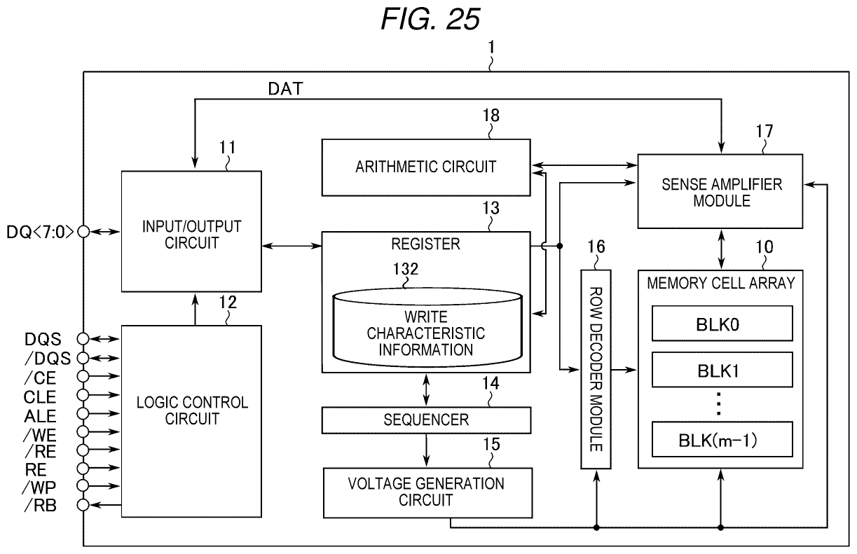

A configuration of the semiconductor memory device 1 according to a third modification will be described with reference to FIG. 25. FIG. 25 is a block diagram showing an example of the configuration of the semiconductor memory device according to the third modification.

The register 13 is provided with write characteristic information 132. The write characteristic information 132 stores a loop operation number in which writing to each verification target level for each page is expected to be completed.

An operation of the semiconductor memory device 1 according to the third modification is same as the second operation of the embodiment except that the loop operation in which writing to each verification target level is expected to be completed is set for each page based on the write characteristic information 132.

The third modification also provides the effects equivalent to those of the embodiment.

### 3. OTHERS

While certain embodiments have been described, these embodiments are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first word line;
a plurality of first memory cells having gates connected to the first word line; and
a control circuit configured to, in a first write operation for setting the plurality of first memory cells to a first state:
repeatedly execute a loop operation of sequentially executing a verification operation of confirming a threshold voltage and a program operation of raising a threshold voltage,
execute a first sensing operation and a second sensing operation in the verification operation of a first loop operation,
the first sensing operation being an operation of determining whether a threshold voltage of each of the plurality of first memory cells is equal to or higher than a first voltage,
the second sensing operation being an operation of determining whether the threshold voltage of each of the plurality of first memory cells is equal to or higher than a second voltage higher than the first voltage, and
not execute the first sensing operation in the verification operation of a second loop operation that is after the first loop operation.

2. The semiconductor memory device according to claim 1, wherein the control circuit is configured to, in the first loop operation:
raise the threshold voltage under a first programming condition for one of the first memory cells for which the threshold voltage is determined to be lower than the first voltage in the first sensing operation,
raise the threshold voltage under a second programming condition in which an amount of increase of the threshold voltage is smaller than that of the first programming condition for one of the first memory cells for which the threshold voltage is determined to be equal to or higher than the first voltage in the first sensing operation and determined to be lower than the second voltage in the second sensing operation, and
inhibit raising of the threshold voltage for one of the first memory cells for which the threshold voltage is determined to be equal to or higher than the second voltage in the second sensing operation.

3. The semiconductor memory device according to claim 2, wherein the control circuit is configured to execute the second sensing operation in the second loop operation.

4. The semiconductor memory device according to claim 3, wherein the control circuit is configured to, in the second loop operation:
raise the threshold voltage under the second programming condition for one of the first memory cells for which the threshold voltage is determined to be lower than the second voltage in the second sensing operation, and
inhibit raising of the threshold voltage for one of the first memory cells for which the threshold voltage is determined to be equal to or higher than the second voltage in the second sensing operation.

5. The semiconductor memory device according to claim 3, wherein the control circuit sets the plurality of first memory cells to the first state after execution of the second loop operation.

6. The semiconductor memory device according to claim 2, wherein the control circuit is configured to not execute the second sensing operation in the second loop operation depending on a first result of the first sensing operation and the second sensing operation executed before the second loop operation.

7. The semiconductor memory device according to claim 6, wherein
the control circuit is configured to, in the first write operation, execute the first sensing operation and the second sensing operation in the verification operation of a third loop operation immediately before the first loop operation, and
the first result is a result of the first sensing operation and the second sensing operation in the third loop operation.

8. The semiconductor memory device according to claim 6, wherein the control circuit is configured to, in the first write operation:
calculate a count value that is a number of the first memory cells having a threshold voltage between the first voltage and the second voltage based on the first result,
execute the second sensing operation in the second loop operation when the count value is equal to or greater than a first value, and
not execute the first sensing operation and the second sensing operation in the second loop operation when the count value is less than the first value.

9. The semiconductor memory device according to claim 8, wherein the control circuit is configured to, in the second loop operation:
when the count value is equal to or greater than the first value, raise the threshold voltage under the second programming condition for one of the first memory cells for which the threshold voltage is determined to be lower than the second voltage in the second sensing operation of the second loop operation, and inhibit raising of the threshold voltage for one of the first memory cells for which the threshold voltage is determined to be equal to or higher than the second voltage in the second sensing operation of the second loop operation, and
when the count value is less than the first value, raise the threshold voltage under the second programming condition for one of the first memory cells for which the threshold voltage is determined to be lower than the first voltage based on the first result, and inhibit raising of the threshold voltage for one of the first memory cells for which the threshold voltage is determined to be equal to or higher than the first voltage based on the first result.

10. The semiconductor memory device according to claim 1, further comprising:
a second word line; and
a plurality of second memory cells having gates connected to the second word line, wherein
the control circuit is configured to, in a second write operation of setting the plurality of second memory cells to the first state:
repeatedly execute a loop operation of sequentially executing a verification operation of confirming a threshold voltage and a program operation of raising a threshold voltage,
execute the first sensing operation and the second sensing operation in the verification operation of a third loop operation, and
not execute the first sensing operation in the verification operation of a fourth loop operation after the third loop operation, and
a number of loop operations carried out in the first write operation between the first loop operation and the second loop operation is different from a number of loop operations carried out in the second write operation between the third loop operation and the fourth loop operation.

11. The semiconductor memory device according to claim 10, further comprising:
a register, wherein
the register stores an ordinal number of the second loop operation in the total number of loop operations carried out in the first write operation and an ordinal number of the fourth loop operation in the total number of loop operations carried out in the second write operation.

12. A semiconductor memory device comprising:
a first word line;
a plurality of first memory cells having gates connected to the first word line; and
a control circuit configured to, in a first write operation for setting the plurality of first memory cells to a first state:
repeatedly execute a loop operation of sequentially executing a verification operation of confirming a threshold voltage and a program operation of raising a threshold voltage,
when a write characteristic of the plurality of first memory cells is a first characteristic, execute a first sensing operation and a second sensing operation in the verification operation of a first loop operation in the first write operation,
the first sensing operation being an operation of determining whether a threshold voltage of each of the plurality of first memory cells is equal to or higher than a first voltage,
the second sensing operation being an operation of determining whether a threshold voltage of each of the plurality of first memory cells is equal to or higher than a second voltage higher than the first voltage, and
not execute the first sensing operation in the first loop operation when the write characteristic of the plurality of first memory cells is a second characteristic different from the first characteristic.

13. The semiconductor memory device according to claim 12, wherein
the first characteristic is that the first write operation is completed in a loop operation different from the first loop operation, and
the second characteristic is that the first write operation is completed in the first loop operation.

14. The semiconductor memory device according to claim 13, wherein the control circuit is configured to:
execute the first sensing operation and the second sensing operation in the verification operation of a second loop operation executed before the first loop operation, and
determine the write characteristic of the plurality of first memory cells based on a result of the first sensing operation and the second sensing operation of the second loop operation.

15. The semiconductor memory device according to claim 12, further comprising:
a second word line; and
a plurality of second memory cells having gates connected to the second word line, wherein
the control circuit is configured to, in a second write operation for setting the plurality of second memory cells to the first state, determine an ordinal number of a loop operation in which the second write operation is to be completed to be the same as an ordinal number of the first loop operation in the first write operation.

16. The semiconductor memory device according to claim 15, further comprising:
a register, wherein
the register is configured to store the ordinal number of the first loop operation in the first write operation.

17. A method of performing a write operation in a semiconductor memory device including a first word line and a plurality of first memory cells having gates connected to the first word line, said method comprising:
in a first write operation for setting the plurality of first memory cells to a first state, repeatedly executing a loop operation of sequentially executing a verification operation of confirming a threshold voltage and a program operation of raising a threshold voltage, wherein
a first sensing operation and a second sensing operation are executed in the verification operation of a first loop operation, the first sensing operation being an operation of determining whether a threshold voltage of each of the plurality of first memory cells is equal to or higher than a first voltage, the second sensing operation being an operation of determining whether the threshold voltage of each of the plurality of first memory cells is equal to or higher than a second voltage higher than the first voltage, and
the first sensing operation is not executed in the verification operation of a second loop operation that is after the first loop operation.

18. The method of claim 17, further comprising:
in the first loop operation:
raising the threshold voltage under a first programming condition for one of the first memory cells for which the threshold voltage is determined to be lower than the first voltage in the first sensing operation;
raising the threshold voltage under a second programming condition in which an amount of increase of the threshold voltage is smaller than that of the first programming condition for one of the first memory cells for which the threshold voltage is determined to be equal to or higher than the first voltage in the first sensing operation and determined to be lower than the second voltage in the second sensing operation; and
inhibiting raising of the threshold voltage for one of the first memory cells for which the threshold voltage is determined to be equal to or higher than the second voltage in the second sensing operation.

19. The method of claim 18, wherein the second sensing operation is executed in the second loop operation.

20. The method of claim 19, further comprising:
in the second loop operation:
raising the threshold voltage under the second programming condition for one of the first memory cells for which the threshold voltage is determined to be lower than the second voltage in the second sensing operation; and
inhibiting raising of the threshold voltage for one of the first memory cells for which the threshold voltage is determined to be equal to or higher than the second voltage in the second sensing operation.
